(19) United States
(12) Patent Application Publication
(10) Pub. No.: US 2011/0192451 A1
(43) Pub. Date: Aug. 11, 2011

(54) METAL SUBSTRATE WITH INSULATION LAYER AND METHOD FOR MANUFACTURING THE SAME, SEMICONDUCTOR DEVICE AND METHOD FOR MANUFACTURING THE SAME, AND SOLAR CELL AND METHOD FOR MANUFACTURING THE SAME

(75) Inventors: Keigo SATO, Kanagawa (JP); Ryuichi NAKAYAMA, Kanagawa (JP); Shigenori YUYA, Kanagawa (JP); Shinya SUZUKI, Kanagawa (JP); Shuji KANAYAMA, Kanagawa (JP)

(73) Assignee: FUJIFILM CORPORATION, Tokyo (JP)

(21) Appl. No.: 13/022,364

(22) Filed: Feb. 7, 2011

(30) Foreign Application Priority Data
Feb. 8, 2010 (JP) 2010-025776
Dec. 10, 2010 (JP) 2010-276079

(51) Int. Cl. H01L 31/0216; H01L 23/58; H01L 21/31; H01L 33/44; C25D 11/04; C25D 11/06; H01L 31/04; B23K 31/02; B23K 20/02

(52) U.S. Cl. 136/252; 257/632; 438/778; 438/62; 205/50; 205/324; 228/116; 257/E33.06; 257/E23.002; 257/E21.24

(57) ABSTRACT

A metal substrate with an insulation layer has a metallic substrate having at least an aluminum base, and an insulation layer formed on the aluminum base of the metallic substrate. The insulation layer is a anodized film of aluminum that has a porous structure having plural pores and a Martens hardness of 1000 N/mm² to 3500 N/mm². A ratio of an average pore size of the plural pores to an average wall thickness of the plural pores ranges from 0.2 to 0.5.

### BACKGROUND OF THE INVENTION

1. Field of the Invention

The present invention relates to a metal substrate with an insulation layer having a porous anodized film serving as an insulation layer and a method for manufacturing the same, a semiconductor device and a method for manufacturing the same, and a solar cell and a method for manufacturing the same. The invention especially relates to a metal substrate with an insulation layer having long-term reliability for insulation performance, a semiconductor device and a solar cell using the metal substrate with an insulation layer, and a method for manufacturing a metal substrate with an insulation layer, a method for manufacturing the semiconductor device using the metal substrate with an insulation layer and a method for manufacturing the solar cell.

2. Description of the Background Art

Recently, attempts have been made to form an anodized film on a metal base to be used as an insulation film.

This anodized film in general is believed to be loaded with tensile stress at room temperature. That is, there is a tensile strain in the anodized film, and if the stress is concentrated in the inside of the anodized film, on the surface of the anodized film, or at the interface between the anodized film and the metal base, crack generation and propagation occur easily, resulting in a cracking resistance problem. Especially, when a substrate on which an anodized film is formed as an insulation layer is used as a substrate for an electronic device which needs insulation, if cracks are formed on the insulation layer, the cracks become paths of leak current, resulting in lower insulation performance. Furthermore, the leak current using the cracks as paths, in the worst case, could cause insulation breakdown. As a result, using a substrate with an anodized film as an insulation substrate poses a problem in long-term reliability.

Cracking resistance of an anodized film can be effectively improved by providing a tougher anodized film and controlling the spread of the cracking. Toughness is related to hardness, and anodization with a low hardness is preferably used for controlling the spread of cracks.

Generally, an anodized film with a low hardness can be obtained by using a high temperature during anodizing treatment. For example, JP 2009-267337 A discloses an anodizing treatment using an electrolytic solution including sulfuric acid, phosphoric acid or oxalic acid, or a solution including the mixture thereof at a temperature between 5° C. and 70° C.

The spread of cracks can be effectively suppressed by controlling the internal stress of the anodized film to be compressive stress. The internal stress of conventional anodized film is described in JP 61-19796 A etc.

JP 61-19796 A indicates that, in an anodized film of 3 μm or more, an internal stress becomes a tensile stress. Further, JP 61-19796 A discloses that the strength of the anodized film of aluminum can be enhanced by reducing stress in the tensile direction. An anodized film loaded with a compressive stress at room temperature is considered to have less cracks and excellent cracking resistance because a compressive strain is applied to the film even when the inside of the anodized film, the surface of the anodized film, and the aluminum interface of the anodized film have stress concentration points from time-dependent changes.

However, an anodized film has compressive stress when the film thickness is less than 3 μm, and a tensile stress appears when the film thickness is 3 μm or more. The reason will be explained below.

Generally, an anodized film obtained in an acid electrolytic solution consists of a dense layer called a barrier layer which exists near the interface with aluminum, and a layer having a porous structure called a porous layer which exists in the surface side. The barrier layer has compressive stress. This is because formation of anodized aluminum from single aluminum is accompanied with volume expansion. On the other hand, the porous layer is known to have tensile stress. Therefore, it is known that when the film thickness of the anodized film is large, the anodized film as a whole is largely under the influence of the porous layer, thus the anodized film as a whole shows tensile stress. JP 61-19796 A describes that although an anodized film with a thickness of 3 μm or less has compressive stress, when the thickness exceeds 3 μm, it changes to tensile stress.

### SUMMARY OF THE INVENTION

When an anodized film is formed by anodizing at a high temperature exceeding 50° C. using common acid such as sulfuric acid, phosphoric acid, and oxalic acid, depending on conditions such as concentration and electrolysis voltage, the formation limit of the anodized film, which is called critical film thickness, may be reached, resulting in six problems indicated below.

The first problem is that since the wall portion of the anodized film having a porous structure becomes relatively thin, the durability as an insulation film degrades.

The second problem is that the specific surface area of the anodized film having a porous structure becomes larger and the long-term degradation caused by adsorbed moisture of the anodized film accelerates.

The third problem is that the poor surface properties make it difficult to uniformly form a layer on the anodized film.

The fourth problem is that when forming a layer on the anodized film, the upper layer component easily intrudes into the pores of the anodized film, resulting in lower insulation performance, formation of side reaction products, and loss of reactants.

The fifth problem is that when forming a layer by sputtering or similar methods on the anodized film, the properties of the anodized film itself could be changed due to spattering damage etc.

The sixth problem is that when an anodized film that is thin enough corresponding to the formation limit is formed as the insulation layer in order to prevent the above-mentioned first to fifth problems, insulation performance is insufficient since the film thickness is too small.

As for the necessary film thickness described in the sixth problem above, it is known that the insulation performance of the anodized aluminum depends on the film thickness of the anodized film. When looking at the dielectric breakdown voltage as an indicator of the insulation performance, for example, a semiconductor device or a solar cell requiring high voltage, or a semiconductor device assumed to be operated at a high temperature needs a dielectric strength voltage of hundreds of volts or higher. For example, in an application as a substrate for solar cells, single cells are accumulated on a substrate and a plurality of them are connected in series to provide an output voltage of tens of volts to hundreds of volts. In order to obtain a dielectric breakdown voltage of approximately 200 volts, an anodized film with a thickness of more than approximately 3 μm is required. However, when anodizing at a high temperature exceeding 50° C. to form an anodized film, depending also on conditions such as concentration and electrolysis voltage, the formation limit of the anodized film, which is called critical film thickness, may be reached, and an anodized film with a thickness larger than approximately 3 μm may not be able to be obtained.

On the other hand, it is considered that cracks can be suppressed by providing compressive stress to the anodized film. However, the anodized film described in JP 61-19796 A has tensile stress instead when the film thickness exceeds 3 μm. As mentioned above, since an anodized film with a film thickness of more than 3 μm is required due to insulation performance, a substrate with an anodized film disclosed in JP 61-19796 A is problematic as its use as a metal substrate with an insulation layer.

As a result, an anodized film does not exist that has film thickness large enough to provide sufficient insulation performance, surface properties, right hardness and right internal stress to prevent cracks for a long period of time, etc. Therefore, there is a problem when using an anodized film for semiconductor devices and solar cell substrates which require long-term reliability of insulation performance.

An object of the present invention is to solve the problems in the aforementioned prior art, and to provide a metal substrate with an insulation layer having long-term reliability for insulation and a method for manufacturing the same, a semiconductor device using the metal substrate with an insulation layer and a method for manufacturing the same, and a solar cell and a method for manufacturing the same.

The present invention aims at controlling the Martens hardness of an anodized film and its structure such as the ratio of the average pore size to the average wall thickness to improve the cracking resistance at high temperatures, controlling the internal stress of the anodized film to be a compressive strain to further improve the cracking resistance at high temperatures, and providing an anodized film with a thickness more than several μm to maintain sufficient insulation performance. In the past, an anodized film having all of these properties did not exist, and as described below, its principle is based on a completely different approach from the prior art.

To achieve the above objectives, a first aspect of the present invention provides a metal substrate with an insulation layer having: a metal substrate comprising at least an aluminum base; and an insulation layer formed on the aluminum base of the metal substrate; wherein: the insulation layer is a porous anodized film of aluminum, the Martens hardness of the anodized film is 1000 N/mm² to 3500 N/mm², and the ratio of the average pore size to the average wall thickness is 0.2 to 0.5.

The anodized film has a compressive strain (strain in a compression direction) at room temperature, and the magnitude of the strain is preferably 0.005% to 0.3%.

No attention has been paid to the relation between the strain which an anodized film has and cracking resistance in the prior art. As for the magnitude of the strain, an anodized film with a porous layer portion having a strain in the tensile direction at room temperature is known in JP 3210611 B, etc. However, the present invention is different in that the porous layer portion has a compressive strain at room temperature.

In the present invention, when the compressive strain is less than 0.005%, although the compressive strain exists, the compressive force is not substantially loaded to the anodized film, so the effectiveness of cracking resistance is difficult to obtain. Therefore, when exposed to high-temperature environments when forming a film, when a bending strain is applied to a roll-to-roll manufacturing process and to an end product form, when temperature cycle over a long period of time is experienced, or when an impact or a stress is applied from outside, cracks are formed on the anodized film formed as an insulation layer, resulting in lower insulation performance.

On the other hand, as for the upper limit of the compressive strain, the insulation performance drastically degrades since the anodized film peels off, or a strong compressive strain is applied to the anodized film, causing formation of cracks, and the anodized film to swell to lower the surface flatness and to peel off. Therefore, the compressive strain preferably 0.3% or less. The compressive strain is more preferably not more than 0.20% and especially preferably not more than 0.15%.

In this case, the anodized film is preferably 1 μm to 20 μm in thickness, more preferably 3 μm to 20 μm, even more preferably 3 μm to 15 μm, and especially preferably 5 μm to 15 μm.

The anodized film can have balanced insulation performance due to the film thickness of 3 μm or more, heat resistance when forming a film due to the compressive stress at room temperature, and long-term reliability.

When the film thickness is extremely thin, damages caused by electric insulation and mechanical impact during handling may not be prevented. Furthermore, the effects of time degradation become serious due to the drastic deterioration of insulation performance and heat resistance. This is because, due to the film being thinner, the effect of asperities on the anodized film surface becomes relatively large and cracks tend to form with these as the base points, and additionally, insulation properties diminish because the effects of metal precipitates, intermetallic compounds and voids in the anodized film arising from metal impurities contained in the aluminum become relatively large, and cracks tend to form by fracture when the anodized film incurs external impact or stress. As a result, since the insulation performance degrades when the thickness of the anodized film is less than 3 μm, application as a flexible heat-resistant substrate and the roll-to-roll manufacturing is not suitable.

An excessively large thickness of the film reduces its flexibility and increases the cost and time required for anodization, and thus is not preferred. In addition, bending resistance and thermal strain resistance also degrade. It is estimated that the bending resistance degrades because the magnitudes of the tensile stresses on the surface and the aluminum interface are different when the anodized film is bent, the stress distribution in the cross-sectional direction becomes larger, and a local stress concentration easily occurs. It is estimated that the thermal strain resistance degrades because when tensile stress is applied to the anodized film because of thermal expansion of the base, a larger stress is applied to the portion close to the interface with aluminum, the stress distribution in the cross-sectional direction becomes larger, and a local stress concentration easily occurs. As a result, since the bending resistance and the thermal strain resistance degrade when the thickness of the anodized film exceeds 20 μm, application as a flexible heat-resistant substrate and the roll-to-roll manufacturing is not suitable. Insulation reliability is also lowered.

The anodized film is a porous anodized aluminum film called a porous type. This film includes two layers: a barrier layer and a porous layer. As mentioned above, the barrier layer generally has compressive stress, and the porous layer has tensile stress. However, the anodized film of the present invention is a porous type anodized film consisting of a barrier layer and a porous layer, and the porous layer has compressive stress. Therefore, even a thick film of 3 μm or more can cause the whole anodized film to be loaded with compressive stress. No crack is formed by a thermal expansion difference when forming the film, resulting in an insulation film excellent in long term reliability at near room temperature.

The anodized film may be in an irregular porous structure or in a regular porous structure.

Further, the anodized film is preferably formed by electrolysis in an aqueous solution at a temperature of 50° C. or more, which includes an acid with a pKa of 2.5 to 3.5 at a temperature of 25° C.

The anodized film having a compressive strain is preferably an anodized film obtained by heating the film to 100° C. to 600° C. after anodization.

The anodized film having a compressive strain is preferably an anodized film obtained by heating an anodized film having a tensile strain.

The metal substrate is preferably made of an aluminum base, and the anodized film is preferably formed at least on one side of the aluminum base.

Further, the metal substrate is preferably provided with an aluminum base at least on one side of a metal base.

The metal substrate is formed by providing the aluminum base at least on one side of a metal base made of metal different from aluminum, and the anodized film is preferably formed on the surface of the aluminum base.

Further, the metal substrate is formed by providing an aluminum base on at least one side of a metal base made of metal having a larger Young's modulus than aluminum, and the anodized film is preferably formed on the surface of the aluminum base.

The linear thermal expansion coefficient of the metal base is preferably larger than that of the anodized film, and is smaller than that of aluminum.

Further, the Young's modulus of the metal base is preferably larger than that of the anodized film, and is preferably larger than that of aluminum.

The metal substrate is preferably formed by unifying a metal base and an aluminum base by pressure welding compression bonding).

Further, the metal substrate with an insulation layer of the present invention includes a metal substrate provided at least with an aluminum base, and an insulation layer formed on the aluminum base of the metal substrate, wherein the insulation layer is a porous anodized film of the aluminum, and the anodized film is under the influence of a compressive stress at room temperature, and the magnitude of the compressive stress is 2.5 MPa to 450 MPa.

A second aspect of the present invention provides a method for manufacturing a metal substrate with an insulation layer in which an anodized film of aluminum is formed as an insulation layer on an aluminum base of a metal substrate that comprises at least the aluminum base, wherein the anodized film is formed in an aqueous solution at a temperature of 50° C. or higher including an acid with a pKa of 2.5 to 3.5 at a temperature of 25° C.

In this case, the metal substrate preferably has an aluminum base formed at least on one side of a metal base, and the metal base and the aluminum base are preferably formed by unifying through pressure welding.

Further, the anodized film is preferably formed using a roll-to-roll process.

A third aspect of the present invention provides a semiconductor device using the metal substrate with an insulation layer of the first aspect of the present invention.

A fourth aspect of the present invention provides a method for manufacturing a semiconductor device comprising the steps of: producing a metal substrate with an insulation layer with the manufacturing method according to the second aspect of the present invention, and manufacturing a semiconductor element on the metal substrate with an insulation layer using a roll-to-roll process.

A fifth aspect of the present invention provides a solar cell using the metal substrate with an insulation layer of the first aspect of the present invention.

In this case, a compound-based photoelectric conversion layer is preferably formed on the metal substrate with an insulation layer.

Further, the photoelectric conversion layer is preferably formed of a compound semiconductor having at least one kind of chalcopyrite structure.

Further, the photoelectric conversion layer is preferably made of at least one kind of compound semiconductors formed of a group Ib element, a group IIIb element, and a group VIb element.

Further, preferably in the photoelectric conversion layer, the group Ib element is at least one selected from the group consisting of Cu and Ag; the group IIIb element is at least one selected from the group consisting of Al, Ga, and In; and the group VIb clement is at least one selected from the group consisting of S, Se, and Te.

A sixth aspect of the present invention provides a method for manufacturing a solar cell comprising the steps of: producing a metal substrate with an insulation layer with the manufacturing method according to the second aspect of the present invention, and forming at least a lower electrode and a photoelectric conversion layer on the metal substrate with an insulation layer using a roll-to-roll process.

According to the present invention, a porous anodized film of aluminum is provided as an insulation layer formed on the surface of the metal substrate comprising at least an aluminum base, and by providing the anodized film with a Martens hardness of 1000 N/mm² to 3500 N/mm², and by setting the ratio of the average pore size to the average wall thickness to be 0.2 to 0.5, cracking resistance enough to control the spread of cracks can be acquired even when cracks are formed on the anodized film. Thereby, good durability of electric insulation can be acquired. Therefore, in case of using it for a substrate of a solar cell, for example, even if it is placed outdoors and subjected to severe temperature changes and external impact, or even if a defect occurs on the aluminum base and the anodized film from time-dependent changes, long-term reliability for electric insulation can be acquired.

Further, even if a compressive strain is applied to the anodized film at room temperature to form a predetermined semiconductor layer, etc. on the metal substrate with an insulation layer in the roll-to-roll process, cracks are hard to form and an excellent bending strain is provided.

Even if cracks are formed on the anodized film by bending, since the compressive strain is applied at room temperature while in use, the cracks are closed at the service temperature, and electric insulation can be maintained.

Further, the compressive strain is applied to the anodized film at room temperature so that even when the metal substrate with an insulation layer is exposed to hot-temperature environments, the tensile stress applied to the anodized film can be reduced because of the difference of the linear thermal expansion coefficient between the anodized film and the metal substrate, defects such as breaks and cracks are not caused, and an excellent resistance to a thermal strain is provided. Therefore, even if it is heated in the film-deposition process of the semiconductor layer, cracks are not easily formed. Thereby, the photoelectric conversion layer of a solar cell is known to have good conversion efficiency when formed at high temperatures, the photoelectric conversion layer can be formed at high temperatures, and an efficient thin-film solar cell can be obtained.

According to the present invention, by forming an anodized film in an aqueous solution at a temperature of 50° C. or higher, which includes an acid with a pKa of 2.5 to 3.5 at a temperature of 25° C., a porous anodized film with a Martens hardness of 1000 N/mm² to 3500 N/mm² and a ratio of the average pore size to an average wall thickness of 0.2 to 0.5 can be formed.

### BRIEF DESCRIPTION OF DRAWINGS

FIG. 1A is a cross section view schematically illustrating a metal substrate with an insulation layer according to an embodiment of the present invention; FIG. 1B is a cross section view schematically illustrating another examples of the metal substrate with an insulation layer according to an embodiment of the present invention; FIG. 1C is a cross section view schematically illustrating another example of the metal substrate with an insulation layer according to an embodiment of the present invention;

FIG. 2 is a graph showing schematically the strain applied to a conventional anodized film, and an anodized film with a compressive strain of 0.09% and 0.16%;

FIG. 3 is a graph which schematically illustrates the strain applied to the anodized film the cases where the linear thermal expansion coefficient of the composite substrate is 17 ppm/K and 10 ppm/K, and a conventional anodized film;

FIG. 4 is a graph showing schematically a heat treatment condition with the annealing temperature on the vertical axis and the annealing time on the horizontal axis;

FIG. 5 is a cross section view schematically illustrating a thin-film solar cell using the metal substrate with an insulation layer according to an embodiment of the present invention;

FIG. 6 is a schematic view illustrating crack length/indentation length;

FIGS. 7A to 7F are photographs illustrating the cross sections of the anodized film formed under the anodization conditions A to D, G, and L;

FIGS. 8A to 8F are photographs illustrating indentation formed to measure crack length/indentation length of the anodized film formed under the anodization conditions A to D, G, and L; and

FIGS. 9A to 9F are photographs illustrating the cross sections of the anodized film formed under the anodization conditions N, P, Q, R, V, and W.

### DETAILED DESCRIPTION OF THE INVENTION

On the following pages, a metal substrate with an insulation layer and a method for manufacturing the same, a semiconductor device and a method for manufacturing the same, and a solar cell and a method for manufacturing the same according to the present invention are described in detail with reference to the preferred embodiments shown in the accompanying drawings.

The metal substrate with an insulation layer of the embodiment will be described below.

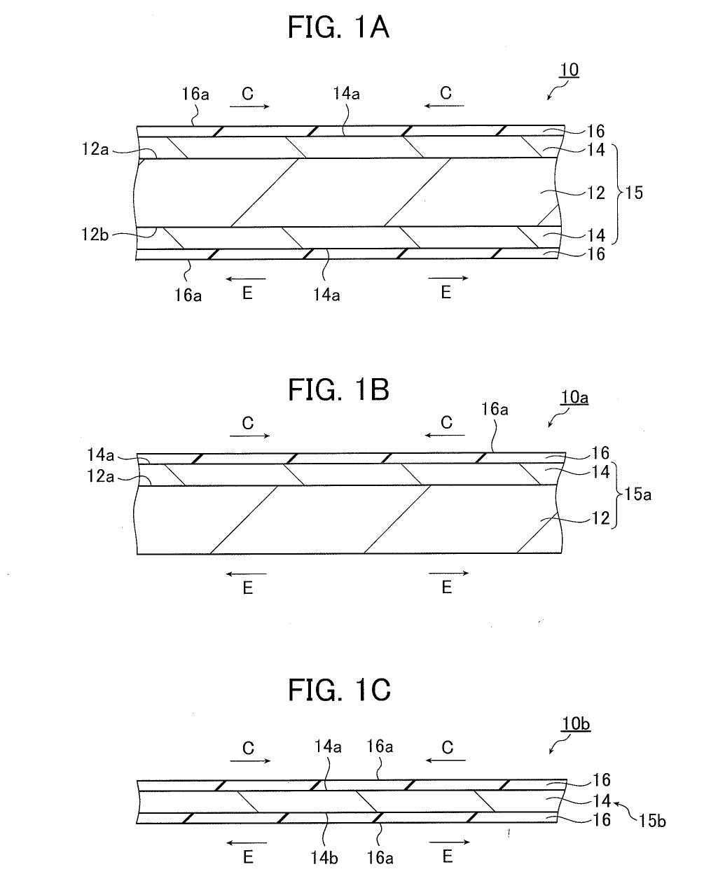

As shown in FIG. 1A, the substrate 10 is a metal substrate with an insulation layer comprising a metal base 12, an aluminum base 14 (hereinafter referred to as an Al base 14) that has aluminum as its main component, and an insulation layer 16 that electrically insulates the metal base 12 and the Al base 14 from outside. This insulation layer 16 is formed with an anodized film.

In the substrate 10, the Al base 14 is formed on the front surface 12a of the metal base 12, and the insulation layer 16 is formed on the front surface 14a of the Al base 14. Further, the Al base 14 is formed on the back surface 12b of the metal base 12, and the insulation layer 16 is formed on the front surface 14a of the Al base 14. In the substrate 10, the Al bases 14 and the insulation layers 16 are placed symmetrically with the metal base 12 in the center.

Note that the metal base 12 and two Al bases 14 are laminated and unified to form a metallic substrate 15.

The substrate 10 of the embodiment is used as a substrate of a semiconductor device, a photoelectric conversion element, and a thin-film solar cell, and is flat in shape for example. The shape and size of the substrate 10 are suitably determined in accordance with the size, etc., of the semiconductor device, the photoelectric conversion element, and the thin-film solar cell in which it is applied. When used in a thin-film solar cell, the substrate 10 is square in shape with the length of one side exceeding 1 m, for example.

In the substrate 10, metal different from aluminum is used for the metal base 12. For this different metal, for example, metal or alloy with Young's modulus larger than aluminum and aluminum alloy is used. Furthermore, the metal base 12 preferably has a linear thermal expansion coefficient (coefficient of linear thermal expansion) larger than that of the anodized film forming the insulation layer 16, and smaller than that of aluminum. Further, the metal base 12 preferably has the Young's modulus larger than that of the anodized film forming the insulation layer 16, and larger than that of aluminum.

Considering the facts described above, in this embodiment, steel materials, such as carbon steel and ferrite stainless steel, are used in the metal base 12. Further, since the above-mentioned steel materials used for the metal base 12 have greater strength in temperatures of 300° C. and higher than aluminum alloy, good heat resistance can be achieved in the substrate 10.

The carbon steel used for the metal base 12 is a carbon steel for mechanical structures having a carbon content of 0.6 mass % or less, for example. Examples of materials used as the carbon steel for a mechanical structure include materials generally referred to as SC materials.

Further, the materials that can be used as the ferrite stainless steel include SUS430, SUS405, SUS410, SUS436, and SUS444.

Examples of materials that can be used as the steel material in addition to the above include materials generally referred to as SPCC materials (cold-rolled steel sheets).

Note that, other than the above, the metal base 12 may be made of a kovar alloy (5 ppm/K), titanium, or a titanium alloy. The material used as titanium is pure titanium (9.2 ppm/K), and the material used as the titanium alloy is Ti-6Al-4V and Ti-15V-3Cr-3Al-3Sn, which are wrought alloys. These metals also are used in a flat shape or foil shape.

The thickness of the metal base 12 affects flexibility, and is thus preferably thin, within a range not associated with an excessive lack of rigidity.

In the substrate 10 in this embodiment, the thickness of the metal base 12 is, for example, 10 μm to 800 μm, and preferably 30 μm to 300 μm. More preferably, the thickness is 30 μm to 150 μm. It is especially preferably 30 μm to 100 μm. The reduced thickness of the metal base 12 is also preferred from a raw material cost standpoint.

When the metal base 12 is a material that is to be flexible, the metal base 12 employed is preferably ferrite stainless steel.

The Al base 14 comprises aluminum as its main component, meaning that the aluminum content is at least 90 mass %.

Examples of materials used as the Al base 14 include aluminum and aluminum alloy.

The Al base 14 can be formed, for example, of publicly known materials indicated in Aluminum Handbook, 4th edition (published in 1990 by Japan Light Metal Association) including, more specifically, Class 1000 alloys such as JIS1050 material and JIS1100 material, Class 3000 alloys such as JIS3003 material, JIS3004 material, and JIS3005 material, Class 6000 alloys such as JIS6061 material, JIS6063 material, and JIS6101 material, and internationally registered alloy 3103A etc.

The aluminum or aluminum alloy used for the Al base 14 preferably does not contain any unnecessary intermetallic compounds. Specifically, aluminum with a purity of at least 99 mass % which contains few impurities is preferred. For example, 99.99 mass % Al, 99.96 mass % Al, 99.9 mass % Al, 99.85 mass % Al, 99.7 mass % Al, and 99.5 mass % Al are preferred. Thus, increasing the purity of the aluminum of the Al base 14 makes it possible to avoid occurring intermetallic compounds, which cause deposits, and increase the integrity of the insulation layer 16. In a case where an aluminum alloy is anodized, the possibility exists that intermetallic compounds will become the origin of poor insulation; and this possibility increases as the amount of intermetallic compounds increases.

Especially, when a material with the purity of 99.5 mass %, or 99.99 mass % or more is used as the Al base 14, disturbance of the regular formation (hereinafter referred also to as regularization) of the micropore of the anodized film described later is controlled, thus the above material is preferred Disturbance of the regularization of anodized film can provide a starting point for cracks when a thermal strain is applied. For this reason, the Al base 14 has higher heat resistance when purity is higher.

Further, as described above, more cost effective industrial aluminum can also be used for the Al base 14. However, in terms of insulation properties of the insulation layer 16, it is preferable for Si not to precipitate out in the Al base 14.

In the substrate 10, the insulation layer 16 is for electric insulation and preventing damage from mechanical impact during handling. The insulation layer 16 is made of an anodized film (an alumina film, Al₂O₃ film), which is formed of anodization of aluminum, and the anodized film has a porous structure. Hereafter, an anodized film with the porous structure is referred to as a porous anodized film, or simply an anodized film.

The Martens hardness of the porous anodized film forming the insulation layer 16 is 1000 N/mm² to 3500 N/mm², and the ratios of the average pore size of plural pores to the average wall thickness of the plural pores (the average pore size/average wall thickness) is 0.2 to 0.5. Thus, the spread of cracks can be suppressed and cracking resistance can be acquired.

The average wall thickness and the average pore size are respectively the average value of the wall thickness and the average value of the pore size obtained by measuring the wall thickness and the pore size from 20 cells among the cells (pores) formed in the anodized film by observing the anodized film with a scanning electron microscope.

The Martens hardness of the porous anodized film forming the insulation layer 16 is preferably 1500 N/mm² to 3500 N/mm², more preferably 1500 N/mm² to 3000 N/mm², and especially preferably 2000 N/mm² to 3000 N/mm². The ratio of the average pore size to the average wall thickness is preferably 0.3 to 0.5, more preferably 0.3 to 0.45, and especially preferably 0.3 to 0.4.

When the Martens hardness exceeds 3500 N/mm², the toughness of the anodized film degrades, stress relaxation becomes impossible when thermal stress, bending stress, etc. is applied, cracks are easily formed, and cracks are easily spread. On the other hand, when the Martens hardness is less than 1000 N/mm², the durability of the insulation layer 16 degrades, and when a layer is formed by spattering, etc. on the insulation layer 16, damage caused by spattering, etc. could change the properties of the anodized film.

When the ratio of the average pore size to the average wall thickness is less than 0.2, the toughness of the anodized film degrades, stress relaxation becomes impossible when thermal stress, bending stress, etc. is applied, cracks are easily formed, and cracks are easily spread. On the other hand, when the ratio of the average pore size to the average wall thickness exceeds 0.5, although cracks are not easily formed due to decrease of the hardness, the durability as an insulation layer degrades since the wall thickness becomes relatively small.

Further, the Vickers hardness of the porous anodized film is preferably approximately 100 to 500, and especially preferably 100 to 350.

In the substrate 10, the insulation layer 16 is for electric insulation and preventing damage from mechanical impact during handling. This insulation layer 16 is made of an anodized film (an alumina film, Al₂O₃ film) formed by anodization of aluminum.

The anodized film forming the insulation layer 16 has a compressive strain (strain in the direction of compression C) at room temperature (23° C.), and the magnitude of the strain is 0.005% to 0.3%. A tensile strain usually exists in the anodized film of aluminum.

When the compressive strain is less than 0.005%, although the compressive strain exists, compression force is not substantially applied to the anodized film used as the insulation layer 16, and effectiveness of cracking resistance is difficult to obtain. Therefore, the compressive strain is preferably 0.005% or more, more preferably 0.02% or more, and still more preferably 0.05% or more. On the other hand, the upper limit of the compressive strain is 0.3%, considering when a larger compressive strain is applied to the anodized film used as the insulation layer 16, it causes cracks to form and the anodized film to swell lowering the surface flatness, resulting in the film coming off. More preferably it is 0.2% or less, and especially preferably 0.15% or less.

Since the past, in a metal substrate with an insulation layer in which an anodized film is formed on the metal substrate as an insulation layer, the topics of concern have been heat resistance during the manufacture of semiconductor elements, bending resistance as a flexible substrate during roll-to-roll manufacturing, and long-term durability and strength.

The issue in heat resistance is caused by fracture of the anodized film when the anodized film cannot withstand the stretch of the metal substrate when exposed to high temperatures. This is because there is a large difference of the linear thermal expansion coefficients between the metal substrate and the anodized film.

For example, the linear thermal expansion coefficient of aluminum is 23 ppm/K, and the linear thermal expansion coefficient of the anodized film is 4 ppm/K to 5 ppm/K. Therefore, at high temperatures when there is a difference of stretch amount due to the difference of the linear thermal expansion coefficients, the anodized film cannot withstand the stretch of the base metal and a tensile force strong enough to fracture the anodized film is applied.

The issue in the bending resistance is caused by fracture of the anodized film when the anodized film cannot withstand the tensile stress applied when it is bent with the anodized film on the outside.

The issues in the durability and the strength are caused by fracture of the anodized film when the anodized film cannot withstand the stress change accompanying disturbances as follows. Specific disturbances include thermal expansion and shrink of the substrate due to rise and fall of heat accompanying operation and shutdown for a long period of time, stress from outside, and stress accompanying property changes and volume changes of an anodized film, a semiconductor layer, a sealing layer, etc. accompanying humidity, temperature, and oxidation, etc.

The inventors of the present invention diligently conducted research and found that by providing a strain to the anodized film in the compression direction at room temperature, an anodized film with heat resistance when manufacturing a semiconductor element, bending resistance in the roll-to-roll manufacturing and as a flexible substrate, durability and strength for a long period of time can be obtained.

The reason why providing a strain to the anodized film in the compression direction at room temperature improves cracking resistance can be explained as follows. Although a mechanism to improve cracking resistance to heat is schematically illustrated as an example, from the viewpoint that fracture of the anodized film caused by tensile force is suppressed, it is assumed that the same kind of mechanism functions regarding overall improvement of cracking resistance to stress from outside such as bending and temperature changes.

As described above, in a conventional anodized film, an internal strain is tensile distortion of approximately 0.005% to 0.06% at room temperature. Further, because the coefficient of linear thermal expansion of the anodized film is approximately 5 ppm/K, and because the coefficient of linear thermal expansion of aluminum is 23 ppm/K, in the case of an anodized film on an aluminum substrate, the anodized film is applied with an tensile strain at a rate of 18 ppm/K due to temperature rise. When the tensile strain of 0.16% to 0.23%, which is the fracture limit of the anodized film, is applied, cracks are formed. This temperature is 120° C. to 150° C. with a conventional anodized film.

On the other hand, with an anodized film according to the present invention, an internal strain is a compressive strain at room temperature. The inventors have confirmed that the coefficient of linear thermal expansion of an anodized film is approximately 5 ppm/K regardless of the type of the film and the coefficient of linear thermal expansion of the anodized film according to the present invention is also approximately 5 ppm/K. Therefore, temperature rise applies a tensile strain to the anodized film at a rate of 18 ppm/K. The fracture limit of the anodized film is estimated to be approximately 0.16% to 0.23% regardless of the type of the film, and it is considered that application of a tensile strain of this magnitude will cause cracks to form.

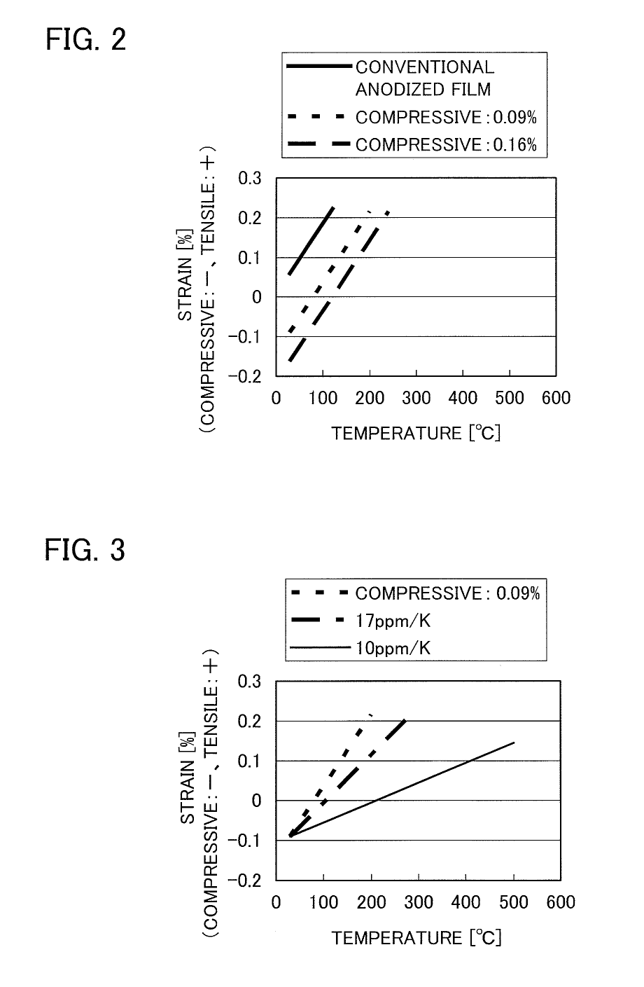

In the case of an anodized film with the compressive strain of 0.005% to 0.3% at room temperature, which is a preferable range, if the tensile strain is assumed to be applied at a rate of 18 ppm/K, the tensile strain of 0.16% to 0.23% is applied at 170° C. to 340° C. FIG. 2 schematically illustrates the tensile strains applied to a conventional anodized film and the anodized film with the compressive strain of 0.09% and 0.16%. As illustrated in FIG. 2, the temperature for cracks to form can be raised by increasing the compressive strain. In reality, because the coefficient of linear thermal expansion of the anodized film is not necessarily constant, there is shrinkage accompanying dehydration of moisture contained in the anodized film, and the rigidity of the substrate is lost with softening of aluminum, it is not completely in matching with the model calculation; however, it has been experimentally confirmed that the temperature for cracks to form can be raised.

Further, by using a composite substrate of aluminum and dissimilar metal as a substrate, the temperature for cracks to form can be further raised. The linear thermal expansion coefficient of the composite substrate can be determined as an average value according to the linear expansion coefficients, Young's moduli and thicknesses of the constituent metal materials. If a composite substrate of aluminum and a metal material having a linear thermal expansion coefficient lower than that of aluminum (23 ppm/K) and greater than or equal to that of the anodized film (5 ppm/K) is used, the linear thermal expansion coefficient of the composite substrate can be made lower than 23 ppm/K, although it also depends on Young's modulus and thickness. FIG. 3 schematically illustrates the tensile strains applied to the anodized film when the coefficient of linear thermal expansion of the compound substrate is 17 ppm/K and 10 ppm/K. Even an anodized film having the same compressive strain at room temperature can raise the temperature for cracks to form by making the coefficient of linear thermal expansion of the substrate smaller. In reality, because the coefficient of linear thermal expansion of the anodized film is not necessarily constant, and there is shrinkage accompanying dehydration of the moisture contained in the anodized film, etc., it is not completely in matching with the model calculation; however, it has been experimentally confirmed that the temperature for cracks to form can be further raised.

The anodized film having a compressive strain at room temperature can be obtained using methods such as one specifically described below. It should of course be understood that it is not limited to these methods.

One method to provide a compressive strain is to anodize the Al base of a metal substrate under a condition that the metal substrate is extended further than its state of usage at room temperature. It is not especially limited as long as, for example, a tensile force can be applied in the tensile direction within the range of elastic deformation or curvature can be kept imparted. For example, when the roll-to-roll process is used, tension during transport is adjusted to provide a tensile force to the metallic substrate 15, or curvature is imparted to the metallic substrate 15 with the shape of a transport path in an anodizing tub as a curved surface. Anodic treatment performed under such a condition provides an anodized film with the magnitude of the compressive strain at room temperature (23° C.) of 0.005% to 0.3%. In this method, the whole anodized film has a compressive strain. That is, both the barrier layer and the porous layer have a compressive strain. This phenomenon was discovered by the inventors while pursuing research of anodized aluminum.

The following method can also be used. Using an aqueous solution with the temperature of 50° C. to 98° C., a metal substrate is anodized under a condition that it is extended further than its state of usage at room temperature, so that when it is returned to the room temperature the compressive strain is applied to the anodized film. In this method, since the temperature of the aqueous solution used for anodization is at most approximately 100° C., the extension of the metal substrate is at most 0.1%. Therefore, the compressive strain of the anodized film will also be 0.1%. Therefore, when the compressive strain is applied to the anodized film using the aqueous solution at the temperature of 50° C. to 98° C., the compressive strain is at most approximately 0.1%. In this method, the whole anodized film has a compressive strain. That is, both the barrier layer and the porous layer have a compressive strain. This phenomenon was discovered by the inventors while pursuing research of anodized aluminum.

Further, the following method can also be used. By annealing the aluminum material that forms the anodized film by raising the temperature to an extent such that the anodized film does not break, when returned to room temperature, it changes to a state where compressive strain acts on the anodized film. The anodized film that is extended at a high temperature experiences a structural change to ease the tensile strain, and the compressive strain is generated in the anodized film in conjunction with shrinkage of the aluminum material when the temperature drops. Thus, with the anodized film kept as it was produced, the whole of the anodized film with a tensile strain can be changed to have a compressive strain. That is, a strain of both the barrier layer and the porous layer change to a compressive strain. Hereafter, the effect of thus changing a tensile strain into a compressive strain is referred to as a compression effect. This phenomenon was discovered by the inventors while pursuing research of anodized aluminum.

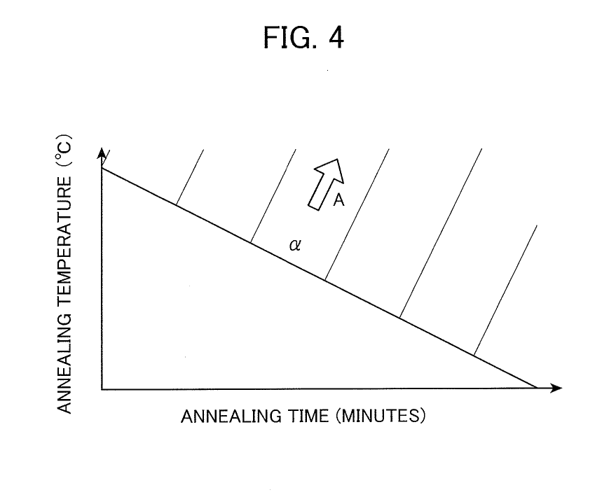

The compression effect can be easily discovered in the area α as schematically illustrated in FIG. 4, and in this area α, the compression effect becomes larger as the area goes in the direction of the arrow head A. Thus, in annealing treatment, the higher the temperature is and the longer it takes, the larger the compression effect will be. This has also been confirmed by the inventors.

The compression effect of the anodized film by this annealing can be obtained regardless of anodization conditions. Thus, electrolytic solution used for anodization includes aqueous electrolytic solution such as an inorganic acid, organic acid, alkali, buffer solution, and combination thereof, and non-aqueous electrolytic solution such as an organic solvent and molten salt. Further, the structure of the anodized film can be controlled by the density, voltage, temperature, etc., of the electrolytic solution; however, in any anodized film, a tensile strain produced in the anodized film by annealing can be changed to a compressive strain.

Furthermore, it has been confirmed that a similar compression effect of changing the strain of the anodized film to compressive strain is obtained whether the atmosphere of annealing is vacuum or air at atmospheric pressure.

The present invention indicates an anodized film applied with a compressive strain; however, the strain and stress are in a linear relation in the elasticity range with the Young's modulus of the material as a multiplier, thus an anodized film applied with compressive stress is a synonymous. The inventors have confirmed that the Young's modulus of the anodized film is 50 GPa to 150 GPa. The range of preferable compressive stress is shown below from this value and the range of the above-mentioned preferable compressive strain.

In the substrate 10, the insulation layer 16 is applied with stress in the compression direction (hereinafter referred to as compressive stress) at room temperature and the magnitude of the compressive stress is 2.5 MPa to 450 MPa. The magnitude of the compressive stress is preferably 5 MPa to 300 MPa, more preferably 5 MPa to 150 MPa, and especially preferably 5 MPa to 75 MPa.

When the compressive stresses less than 2.5 MPa, the compressive stress is not substantially applied to the anodized film used as the insulation layer 16, and the effectiveness of cracking resistance is difficult to obtain. On the other hand, the upper limit of the compressive stress is 450 MPa considering the anodized film used as the insulation layer 16 coming off, and cracks being formed on the anodized film.

Further, as described above, when the aqueous solution with the temperature of 50° C. to 98° C. is used to apply a compressive strain to the anodized film under a condition that the metal substrate is extended further than its state of usage at room temperature, it is difficult to provide a large compressive strain. For this reason, the upper limit is approximately 150 MPa.

In the substrate 10, the thickness of the insulation layer 16 is preferably 1 μm to 20 μm. An excessively large thickness of the insulation layer 16 reduces its flexibility and increases the cost and time required for formation thereof, and is thus not preferred. Further, when the thickness of the insulation layer 16 is extremely thin, damage caused by electric insulation and mechanical impact during handling may not be prevented. Therefore, the thickness is preferably 1 μm to 20 μm, more preferably 3 μm to 20 μm, still more preferably 3 μm to 15 μm, and especially preferably 5 μm to 15 μm.

The front surface 16a of the insulation layer 16 has a surface roughness in terms of, for example, arithmetic mean roughness Ra is 1 μm or less, preferably 0.5 μm or less, and more preferably 0.1 μm or less.

The substrate 10 includes the metal base 12, the Al base 14, and the insulation layer 16 which are all made of flexible materials, and is therefore flexible as a whole. Thus, on the insulation layer 16 side of the substrate 10, a semiconductor element, a photoelectric conversion element, or the like can be formed by the roll-to-roll process for example.

Further, although the substrate 10 in this embodiment has a structure with the Al base 14 and the insulation layer 16 formed on both sides of the metal base 12, in the present invention, as shown in FIG. 1B, the Al base 14 and the insulation layer 16 may be formed only on one side of the metal base 12. Thus, the substrate 10a can be thinner and lower in cost by using the metallic substrate 15a having the two-layer clad structure of the metal base 12 of stainless steel and the Al base 14.

Furthermore, in this embodiment, although the metallic substrate 15 has the two-layer structure of the metal base 12 and the Al base 14, in the present invention, since there should only be the Al base 14, the metal base 12 may be formed of the same Al base as the Al base 14; therefore, the metal substrate may be formed only of the Al base, and as the shown with the substrate 10b illustrated in FIG. 1C, the metallic substrate 15b may be formed only of the Al base 14. The metal bases 12 of the metal substrates 15 and 15a may have two or more layers.

Next, the method of measuring the strain of the anodized film serving as the insulation layer 16 is described.

In the present invention, the length of the anodized film is first measured in the state of the substrate 10.

Next, the metallic substrate 15 is dissolved and removed, and the anodized film is taken from the substrate 10. Then, the length of the anodized film is measured.

The strain is determined from this length before and after removal of the metallic substrate 15.

When the length of anodized film is longer after the metallic substrate 15 is removed, the compression force is applied to the anodized film. That is, the compressive strain is applied to the anodized film. On the other hand, when the length of the anodized film is shorter after the metallic substrate 15 is removed, the tensile force is applied to the anodized film. That is, the strain in the tensile direction is applied to the anodized film.

Note that the length of the anodized film before and after removal of the metallic substrate 15 may be the length of the entire anodized film or the length of a portion of the anodized film.

In a case where the metallic substrate 15 is dissolved, the solution used may be a copper chloride hydrochloric acid aqueous solution, a mercury chloride hydrochloric acid aqueous solution, a tin chloride hydrochloric acid aqueous solution, an iodine methanol solution, etc. The solution for dissolving is appropriately selected in accordance with the composition of the metallic substrate 15.

In addition to removal of the metallic substrate 15, the warpage and deflection of a metal base having a high planarity for example, are measured, an anodized film is formed on only one side of the metal base, and then the warpage and deflection of the metal base after formation of the anodized film are measured. The warpage and deflection values before and after formation of the anodized film are then used to obtain the strain.

The warpage and deflection of the metal base are measured using, for example, an optically precise measurement method employing a laser. Specifically, the various measurement methods described in the “Journal of the Surface Finishing Society of Japan,” 58, 213 (2007), and in “R&D Review of Toyota CRDL” 34, 19 (1999) may be used to measure the warpage and deflection of the metal base.

The strain of the anodized film serving as the insulation layer 16 may be measured as described below. In this case, the length of the thin film of aluminum is measured first. Next, the anodized film is formed on the thin film of the aluminum, and the length of the thin film of the aluminum at this time is measured. The shrinkage is calculated from the length of the thin film of the aluminum before and after the anodized film is formed, and is converted into the strain.

Note that, since all of the methods measure the strain of the anodized film with the metallic substrate 15 remained except for the method to remove the metallic substrate 15, it is difficult to say that the influence of the metallic substrate 15 can be completely removed. Therefore, if the method to remove the metallic substrate 15 is used, the strain of the anodized film itself can be directly measured without any influence of the metallic substrate 15. Therefore, in the measurement of the strain according to the present invention, a method that removes the metallic substrate 15 is preferred for accurately measuring the strain of the anodized film.

Further, the internal stress of the anodized film can be calculated with the formula of material mechanics using the Young's modulus of the anodized film and the strain that exists in the anodized film. The strain can be calculated as described above.

On the other hand, the Young's modulus of the anodized film can be found by conducting an indentation test or a push-in test using a nanoindenter, etc, on the anodized film in the substrate 10 as is.

In addition, the Young's modulus of the anodized film can be found by removing the metallic substrate 15 from the substrate 10, removing the anodized film, and then conducting an indentation test on the removed anodized film using the push-in tester or nanoindenter, etc.

The Martens hardness and Vickers hardness can also be found by conducting an indentation test on the substrate 10 with the anodized film as is, or on the anodized film from the substrate 10 with the substrate 10 removed, using the push-in tester and nanoindenter, etc.

Further, the Young's modulus of the anodized film can be found by conducting a tensile test on or measuring the dynamic viscoelasticity of either a sample in which a thin metallic film such as aluminum was formed on the anodized film, or the anodized film singly remove from the substrate 10.

Note that measuring the Young's modulus and hardness of a thin film using the indention test may adversely affect the metallic substrate 15, and thus the indentation depth generally needs to be suppressed to within about one-third of the thickness of the thin film. For this reason, to accurately measure the Young's modulus and hardness of the anodized film having the thickness of about several tens of micrometers, measurement using a nanoindenter which is capable of measuring the Young's modulus and hardness even with an indentation depth of a few hundred nanometers is preferred.

Needless to say, the Young's modulus and hardness may be measured using methods other than the one described above.

Next, the production method of the substrate 10 of this embodiment will be described.

First, the metal base 12 is prepared. This metal base 12 is formed to a predetermined shape and size suitable to the size of the substrate 10 to be formed.

Then, the Al base 14 is formed on the front surface 12a and on the back surface 12b of the metal base 12. The metallic substrate 15 is thus formed.

The method of forming the Al base 14 on the front surface 12a and on the back surface 12b of the metal base 12 is not particularly limited, provided that an integral bond that can assure adhesion between the steel base 12 and the aluminum base 14 is achieved. As the formation method of the aluminum base 14, for example, vapor-phase methods such as vapor deposition or sputtering, plating, and pressure welding (pressurizing and bonding) after surface cleaning may be used. Pressure-bonding by rolling or the like is the preferred method of forming the aluminum base 14 in terms of cost and mass producibility. For example, when an Al base with the thickness of 50 μm is cladded to the metal base 12 of stainless steel with the thickness of 150 μm by pressure welding to form the metallic substrate 15, the obtained metallic substrate 15 can have the linear thermal expansion coefficient of as low as approximately 10 ppm/K.

Next, the anodized film is formed as the insulation layer 16 on the front surface 14a arid the back surface 12b of the Al base 14 of the metallic substrate 15. The method of forming the anodized film serving as the insulation layer 16 is described below. The anodization treatment can be performed using, for example, a known anodizing device of the so-called roll-to-roll process.

The anodized film serving as the insulation layer 16 can be formed by immersing the metal base 12 serving as the anode in an electrolytic solution together with the cathode and applying voltage between the anode and the cathode. In the case, the metal base 12 forms a local cell with the Al base 14 upon contact with the electrolytic solution, and therefore the metal base 12 contacting the electrolytic solution is to be masked and isolated using a masking film (not shown). That is, the end surface and the back surface of the metal base 15 other than the front surface 14a of the Al base 14 need to be isolated using a masking film (not shown). Note that the method of masking during the anodization treatment is not limited to the use of masking film. Possible masking methods include, for example, a method in which the end surfaces and the back surface of the metallic substrate 15 other than the surface 14a of the Al base 14 are protected using a jig, a method in which water-tightness is ensured using rubber, and a method in which the surfaces are protected using resist material.

The substrate can be obtained by peeling off the masking film (not shown) after anodization treatment. Where necessary, pre-anodization may include steps of subjecting the surface 14a of the Al base 14 to cleaning and polishing/smoothing processes.

During the anodization treatment, an oxidation reaction proceeds substantially in the vertical direction from the front surface 14a of each of the Al base 14 to form the anodized film on the front surface 14a of each of the Al base 14. The anodized film is of a porous type in which a large number of fine columns in the shape of a substantially regular hexagon as seen from above are densely arranged, a micropore having a rounded bottom is formed at the core of each fine column, and at the bottom of each fine column having a barrier layer with a thickness of typically 0.02 μm to 0.4 μm is formed.

Compared to non-porous aluminum oxide single film, this type of porous anodized film has a lower Young's modulus, higher bending resistance, and higher resistance to cracking due to a difference in thermal expansion when heated.

When an aqueous acid is especially used in anodic treatment, in general, the anodization reaction becomes faster as the temperature is higher, and the anodized film is easily burnt, completely dissolved, etc. Further, since the rate of dissolution of the film becomes higher, the formation limit of the anodized film called critical film thickness may be reached. Therefore, in the present invention, the acid with the pKa (acid dissociation constant) at 25° C. of 2.5 to 3.5 is preferably used, and the solution temperature is preferably not less than 50° C. In this case, in terms of the rate of generation of the anodized film, the anodization voltage is preferably 60 V or higher, more preferably 80 V or higher, and especially preferably 100 V or higher. Further, when the anodization voltage is high, an uneven part called a burnt deposit is easily generated on the anodized film, and power cost increases; therefore, the anodization voltage is preferably 300 V or less, more preferably 200 V or less, and especially preferably 150 V or less.

Note that the aqueous solution used for anodization treatment has a boiling point of 100° C.+elevation, but performing the anodization treatment at the boiling point of the aqueous solution is not practical and byproducts (boehmite) are produced to the extent the temperature is high. Thus, the upper limit of the temperature of the aqueous solution is 98° C., which is less than the boiling point, and more preferably 95° C. or less.

However, higher temperatures require higher heat resistance in a manufacturing facility and decrease the durability of the facility, resulting in higher cost. Thus, the temperature is more preferably 80° C. or less, and especially preferably 60° C. or less.

The reason that the preferred pKa at 25° C. is at least 2.5 can be explained by the relationship between the anodized film and the rate of dissolution by the acid. The pKa, that is, the strength of the acid is known to be somewhat correlated with the dissolution speed of the anodized film [as described in the Journal of the Surface Finishing Society of Japan, 20, 506, (1969), for example]. The actual growth of the anodized film is a complex reaction that proceeds as generation of the anodized film by an electrochemical reaction and dissolution of the anodized film by acid simultaneously occur, making the rate of dissolution of the anodized film a primary cause of film formation.

When the pKa is less than 2.5, the rate of dissolution at a high temperature is too high compared to the generation of the anodized film, sometimes causing failure to achieve stable growth of the anodized film and formation of a relatively thin film that reaches the critical film thickness, resulting in an inadequate anodized film serving as the insulation layer.

Even when using the acid with the pKa of 1.0 to 2.5, if the solution temperature is less than 50° C., or if it is 50° C. or higher with the electrolysis voltage of 30 V or higher, the anodized film can be stably generated. By applying the electrolysis voltage of 30 V or higher, an anodization reaction progresses fast. The rate of generation of the porous layer becomes fast enough for the rate of dissolution of a pore wall, the anodized film does not reach the critical film thickness, and stable growth becomes possible. On the other hand, when the electrolysis voltage is high, an uneven part called a burnt deposit is easily generated on the anodized film, and power cost increases; therefore, the electrolysis voltage of anodization is preferably 100 V or less, more preferably 80 V or less, and especially preferably 60 V or less.

On the other hand, the pKa at 25° C. must be 3.5 or less, and more preferably 3.0 or less. When the pKa at 25° C. exceeds 3.5, the rate of dissolution is too slow even at a high temperature compared to the generation of the anodized film, sometimes causing formation of the anodized film to be extremely time consuming and failure to form a thick film due to formation of an anodized film called the barrier type, resulting in an inadequate anodized film serving as an insulation layer. Further, the acid with high pKa needs a high electrolysis voltage to obtain an anodization rate with production aptitude, resulting in increase in power cost. Therefore, anodizing using the acid with low pKa is preferably used.

Acids having a pKa (acid dissociation constant) of 2.5 to 3.5 include, for example, malonic acid (2.60), diglycol acid (3.0), malic acid (3.23), tartaric acid (2.87), and citric acid (2.90). The solution used for anodization may be a mixed solution of such acids having a pKa (acid dissociation constant) of 2.5 to 3.5, other acids, bases, salts, and additives.

In this embodiment, the metal substrate 50 is subjected to anodization treatment in an aqueous solution including an acid having a pKa (acid dissociation constant) of 2.5 to 3.5 at a temperature of 50° C. or more, then an anodized film can be formed with a compressive stress, relatively low hardness, flat surface properties, sufficient mechanical strength, low percentage of voids, and a small amount of absorbed moisture. More specifically, an anodized film can be obtained with the Martens hardness of 1000 N/mm² to 3500 N/mm², and the ratio of the average pore size to the average wall thickness is 0.2 to 0.5. The magnitude of the compressive strain of this anodized film at room temperature (23° C.) is 0.005% to 0.3%. In this case, the magnitude of the compressive stress applied to the anodized film is 2.5 MPa to 450 MPa.

As described above, the anodized film serving as the insulation layer 16 preferably has the thickness of 1 μm to 20 μm. The thickness can be controlled by the accumulated quantity of electricity, that is, the magnitude and electrolysis time of the current under constant current electrolysis, constant voltage electrolysis, or an electrolysis condition with a combination of the two.

After anodic treatment, the metallic substrate 15 with the anodized film serving as the insulation layer 16 formed is annealed. Thereby, the substrate 10 with the compressive strain of 0.005% to 0.3% can be formed on the insulation layer 16.

Annealing treatment is performed at the temperature of 600° C. or less, for example, to the anodized film. Further, the annealing treatment is preferably performed under annealing conditions of a heating temperature of 100° C. to 600° C. and a holding time of 1 second to 100 hours. In this case, the heating temperature of the annealing treatment is not more than the softening temperature of the Al base 14. A predetermined compressive strain can be achieved by changing the annealing conditions. As described above, as shown in FIG. 4, the annealing condition with a higher heating temperature and a longer holding time can provide a larger compressive strain of the anodized film.

An annealing heating temperature of less than 100° C. fails to substantially achieve a compression effect. On the other hand, when the annealing heating temperature of annealing treatment exceeds 600° C., the difference of the linear thermal expansion coefficients between the metal substrate and the anodized film may cause the anodized film to be cracked. Thus, annealing treatment must be performed at a temperature in which the anodized film will not be destroyed. When an aluminum material is used for a metal substrate, aluminum is excessively softened at high temperatures, causing possible deformation of the base; therefore, it preferably 300° C. or less, more preferably 200° C. or less, and especially preferably 150° C. or less. On the other hand, when a metal substrate provided with an aluminum base on at least one side of the metal base made of metal different from aluminum is used, an intermetallic compound is formed at the interface of the aluminum and the metal base at high temperatures, which could in worst cases results in peeling of the interface; therefore, it is preferably 500° C. or less, more preferably 400° C. or less, and especially preferably 300° C. or less.

The holding time of annealing treatment is not less than 1 second since the compression effect can be achieved with a short holding time. On the other hand, even if the annealing holding time exceeds 100 hours, compression effect becomes saturated and thus the upper limit is 100 hours.

When an aluminum material is used for a metal substrate, softening of aluminum and creep phenomenon are more serious when performed for a longer period time, causing possible deformation of the base, and in terms, of productivity, it is preferably 50 hours or less, more preferably 10 hours or less, and especially preferably 1 hour or less. On the other hand, when a metal substrate provided with an aluminum base on at least one side of the metal base made of metal different from aluminum is used, more intermetallic compounds are formed at the interface of the aluminum and the metal base when performed for a longer period of time, which could in worst cases results in peeling of the interface. In terms of productivity also, it is preferably 10 hours or less, more preferably 2 hours or less, and especially preferably 30 minutes or less. Annealing treatment can be a batch type sheet process or the roll-to-roll process. The roll-to-roll process is cost effective since continuous processing is possible.

As shown in FIG. 1C, when the metallic substrate 15b is formed with the Al base 12 alone on the substrate 10, if the heating temperature of the Al base 12 exceeds the softening temperature, the anodized film controls the elongation amount of the substrate, and the metal substrate cannot extend. Therefore, it is difficult to obtain a compression effect and it is impossible to maintain a constant strength. Therefore, when the metal substrate is the Al base singly, the heating temperature of annealing treatment should be not more than the softening temperature of the Al base 12.

In the substrate 10 of the embodiment, the internal stress of the anodized film at room temperature is in a compressive state and the magnitude of the strain is 0.005% to 0.3%, so that the compressive strain is applied to the anodized film of the insulation layer 16, making it difficult for cracks to form and thus achieving excellent cracking resistance. A metal substrate with an insulation layer can be obtained.

Further, the substrate 10 uses an aluminum anodized film as the insulation layer 16. Since this aluminum anodized film is ceramic, chemical changes do not readily occur even at high temperatures, enabling use of the anodized aluminum film as an insulation layer with high reliability without cracking. As a result, the substrate 10 is highly resistant to a thermal strain, and can be used as a heat resistant substrate.

In the substrate 10, the anodized film of the insulation layer 16 is changed to a state of a compressive strain, making it difficult for cracks to form even if the start-to-finish production in the roll-to-roll process is used, and imparting the film with resistance to a bending strain.

When a tensile strain is applied at room temperature and breaks or cracks are formed, the tensile force acts to open up the breaks or cracks, leaving the breaks or cracks open. As a result, the substrate can no longer maintain electrical insulation properties.

Even if a solar cell that uses the substrate 10 placed outdoors is subjected to severe temperature change, external impact, or time-dependent change to cause damage to the anodized film of the Al base 14 and the insulation layer 16, long-term reliability for insulation can be acquired.

When the substrate 10 is exposed to a hot environment of 500° C. or more, for example, the metallic substrate 15 is extended in the tensile direction E (See FIG. 1A), and the difference of the linear thermal expansion coefficients between the anodized film of the insulation layer 16 and the metallic substrate 15 lowers the tensile stress applied to the anodized film, making it difficult for defects, such as breaks and cracks to occur. Thereby, the heatproof temperature can be improved. Thus, the substrate 10 without performance degradation can be obtained even if it is exposed to a hot environment of 500° C. or more. Therefore, a photoelectric conversion layer can be formed at a higher temperature, and an efficient thin-film solar cell can be manufactured.

In addition, use of the substrate 10 makes it possible to manufacture a thin-film solar cell using the roll-to-roll process for example, thereby largely improving productivity.

Further, in the substrate 10, when the metallic substrate 15 has a two-layer clad structure of the metal base 12 of stainless steel material and the Al base 14, anodic treatment is performed while protecting the metal base 12 of stainless steel material, and the anodized film of the insulation layer 16 is formed only on the front surface 14a of the Al base 14, and the back surface of the metallic substrate 15 exposes stainless steel material. However, by annealing treatment in an air atmosphere, an iron-based oxide film which is primarily Fe₃O₄ is formed on the bare surface of the stainless steel material. This oxide film, if selenium is used during formation of the photoelectric conversion layer of the solar cell for example, functions as an anti-Se-corrosion film of stainless steel. Therefore, it serves as an effective substrate in such solar cells using selenium during formation of the photoelectric conversion layer.

Before and after annealing, the hardness of the anodized film is substantially unchanged. It is estimated that although annealing changes the structure inside the anodized film, no effect appears in the hardness since the macrostructure or physical properties do not change.

In the substrate 10 in this embodiment, the porous anodized film forming the insulation layer 16 is provided with the Martens hardness of 1000 N/mm² to 3500 N/mm² and the ratio of the average pore size to the average wall thickness of 0.2 to 0.5, so that even cracks are formed on the anodized film, the spread of the cracks can be suppressed and cracking resistance can be obtained. Thereby, good durability of electric insulation can be acquired. Even if a solar cell that uses the substrate 10 placed outdoors is subjected to severe temperature change, external impact, or time-dependent change to cause damage to the Al base 14 and the anodized film, long-term reliability for insulation can be acquired.

In the substrate 10, the porous anodized film of the insulation layer 16 is changed to a state of a compressive strain, making it difficult for cracks to form even if the start-to-finish production in the roll-to-roll process is used, and imparting the film with resistance to a bending strain. Even if cracks are formed on the substrate 10 by bending, since the compressive strain is applied at room temperature, and therefore, the breaks or cracks are closed at the service temperature, and the electric insulation of the substrate 10 can be maintained. Thus, the substrate 10 has excellent long term reliability in insulation.

When a tensile strain is applied at room temperature and breaks or cracks are once formed, the tensile force acts to open up the breaks or cracks, leaving the breaks or cracks open. As a result, the substrate can no longer maintain electric insulation properties.

When the substrate 10 is exposed to a hot environment of 500° C. or more, for example, the metallic substrate 15 is extended in the tensile direction E (See FIG. 1A), and the difference of the linear thermal expansion coefficients between the anodized film of the insulation layer 16 and the metallic substrate 15 lowers the tensile stress applied to the anodized film, making it difficult for defects such as breaks and cracks to form and providing an excellent resistance to a thermal strain. Therefore, even if it is heated in the film-deposition process of the semiconductor layer, cracks are riot easily formed. Therefore, a photoelectric conversion layer of the thin-film solar cell can be formed at a higher temperature, and an efficient thin-film solar cell can be manufactured.

In addition, use of the substrate 10 makes it possible to manufacture a thin-film solar cell using the roll-to-roll process for example, thereby largely improving productivity.

Next, a thin-film solar cell that uses the metal substrate with an insulation layer of this embodiment is described.

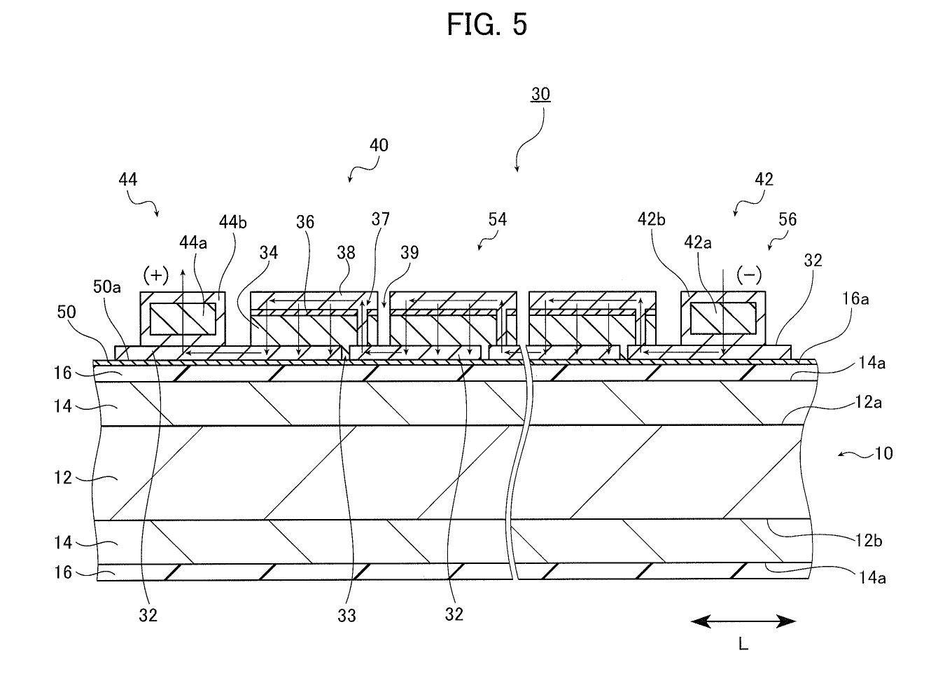

FIG. 5 is a schematic cross-sectional view illustrating a thin-film solar cell using a metal substrate with an insulation layer according to the embodiment of the present invention.

A thin-film solar cell 30 of the embodiment shown in FIG. 5 is used as a solar cell module or a solar cell sub-module constituting this solar cell module, and comprises, for example, a substrate 10 comprising a grounded metallic substrate 15 of substantially rectangular shape and the electrical insulation layer 16 formed on the metallic substrate 15, an alkali supply layer 50 formed on the insulation layer 16, a power generating layer 56 comprising a plurality of power generating cells 54 formed on the alkali supply layer 50 and connected in series, a first conductive member 42 connected to one side of the plurality of the power generating cells 54, and a second conductive member 44 connected to the other side. Note that the body comprising one of the power generating cells (solar cells) 54, the corresponding substrate 10, and the alkali supply layer 50 is herein called a photoelectric conversion element 40, but the thin-film solar cell 30 itself shown in FIG. 5 may be called a photoelectric conversion element.

The thin-film solar cell 30 of this embodiment is formed with the alkali supply layer 50 on the front surface of one of the above-mentioned substrate 10, that is, on the front surface 16a of one insulation layer 16.

The thin-film solar cell 30 includes a plurality of the photoelectric conversion elements 40, the first conductive member 42, and the second conductive member 44.

The photoelectric conversion element 40 functions as a solar cell, and comprises the substrate 10, the alkali supply layer 50, and the power generating cell (solar cell) 54 comprising a back electrodes 32, a photoelectric conversion layers 34, a buffer layer 36, and a transparent electrodes 38.

As described above, the alkali supply layer 50 is formed on the front surface 16a of the insulation layer 16. The back electrodes 32, the photoelectric conversion layers 34, the buffer layers 36, and the transparent electrodes 38 of the power generating cell 54 are layered in that order on a surface 50a of the alkali supply layer 50.

The back electrodes 32 are formed on the surface 50a of the conductive alkali supply layer 50 so as to share a separation groove (P1) 33 with the adjacent back electrodes 32. The photoelectric conversion layer 34 is formed on the back electrodes 32 so as to fill the separation grooves (P1) 33. The buffer layer 36 is formed on the front surface of the photoelectric conversion layer 34. The photoelectric conversion layers 34 and the buffer layers 36 are separated from adjacent photoelectric conversion layers 34 and adjacent buffer layers 36 by grooves (P2) 37 which reach the back electrodes 32. The grooves (P2) 37 are formed in different positions from those of the separation grooves (P1) 33 that separate the back electrodes 32.

The transparent electrode 38 is formed on the surface of the buffer layer 36 so as to fill the grooves (P2) 37.

Opening grooves (P3) 39 are formed so as to reach the back electrodes 32 by penetrating through the transparent electrode 38, the buffer layer 36, and the photoelectric conversion layer 34. In the thin-film solar cell 30, the respective photoelectric conversion elements 40 are electrically connected in series in a longitudinal direction L of the substrate 10 through the hack electrodes 32 and the transparent electrodes 38.

The photoelectric conversion elements 40 of this embodiment are so-called integrated photoelectric conversion elements (solar cells), and have a configuration such that, for example, the back electrode 32 is formed of a molybdenum electrode, the photoelectric conversion layer 34 is formed of a semiconductor compound having a photoelectric conversion function such as, for example, a CIGS layer, the buffer layer 36 is formed of CdS, and the transparent electrode 38 is formed of ZnO.

Note that the photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 5, the first conductive member 42 is connected to the rightmost back electrode 32. The first conductive member 42 is provided to collect the output from the negative electrode as will be described below onto the outside. Although a photoelectric conversion element 40 is formed on the rightmost back electrode 32, that photoelectric conversion element 40 is removed by, for example, laser scribing or mechanical scribing, to expose the back electrode 32.

The first conductive member 42 is, for example, a member in the shape of an elongated strip which extends substantially linearly in the width direction of the substrate 10, and is connected to the rightmost back electrode 32. As shown in FIG. 5, the first conductive member 42 has, for example, a copper ribbon 42a covered with a coating material 42b made of an alloy of indium and copper. The first conductive member 42 is connected to the back electrode 32 by, for example, ultrasonic soldering.

The second conductive member 44 is provided to collect the output from the positive electrode to be described later. Like the first conductive member 42, the second conductive member 44 is a member in the shape of an elongated strip which extends substantially linearly in the width direction of the substrate 10, and is connected to the leftmost back electrode 32. Although a photoelectric conversion element 40 is formed on the leftmost back electrode 32, that photoelectric conversion element 40 is removed by, for example, laser scribing or mechanical scribing, to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-plated copper ribbon. Furthermore, the method of connection of the first conductive member 42 and the second conductive member 44 is not limited to ultrasonic soldering, and they may be connected by such means as, for example, a conductive adhesive or conductive tape.

The photoelectric conversion layer 34 in the photoelectric conversion elements 40 in this embodiment is made of, for example, CIGS, and can be manufactured by a known method of manufacturing CIGS solar cells.

The separation grooves (P1) 33 of the hack electrodes 32, the grooves (P2) 37 reaching the back electrodes 32, and the opening grooves (P3) 39 reaching the back electrodes 32 may be formed by laser scribing or mechanical scribing.

In the thin-film solar cell 30, light entering the photoelectric conversion elements 40 from the side of the transparent electrodes 38 passes through the transparent electrodes 38 and the buffer layers 36, and causes the photoelectric conversion layers 34 to generate electromotive force, thus producing a current that flows, for example, from the transparent electrodes 38 to the back electrodes 32. Note that the arrows shown in FIG. 5 indicate the directions of the current, and the direction in which electrons move is opposite to that of current. Therefore, in the Photoelectric converters 48, the leftmost back electrode 32 has a positive polarity (plus polarity) and the rightmost hack electrode 32 has a negative polarity (minus polarity) in FIG. 5.

In this embodiment, electric power generated in the thin-film solar cell 30 can be output from the thin-film solar cell 30 through the first conductive member 42 and the second conductive member 44.

Also in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the thin-film solar cell 30, and the like.

In this embodiment, the photoelectric conversion elements 40 are formed so as to be connected in series in the longitudinal direction L of the substrate 10 through the back electrodes 32 and the transparent electrodes 38, but the present invention is not limited thereto. For example, the photoelectric conversion elements 40 may be formed so as to be connected in series in the width direction through the back electrodes 32 and the transparent electrodes 38.

The back electrodes 32 and the transparent electrodes 38 of the photoelectric conversion elements 40 are both provided to collect current generated by the photoelectric conversion layers 34. Both the back electrodes 32 and the transparent electrodes 38 are each made of a conductive material. The transparent electrodes 38 must be have translucency.

The back electrodes 32 are formed, for example, of Mo, Cr, or W, or a combination thereof. The back electrodes 32 may have a single-layer structure or a laminated structure such as a two-layer structure. The back electrodes 32 are preferably formed of Mo.

The back electrodes 32 may be formed by any vapor-phase film deposition method such as electron beam vapor deposition or sputtering.

The back electrodes 32 generally have a thickness of about 800 nm, preferably 200 nm to 600 nm, and more preferably 200 nm to 400 nm. By making the back electrodes 32 thinner than standard, it is possible to increase the diffusion speed of the alkali metal from the alkali supply layer 50 to the photoelectric conversion layers 34, as will be described below. Further, with this arrangement, the material costs of the back electrodes 32 can be reduced, and the formation speed of the back electrodes 32 can be increased.

The transparent electrodes 38 are formed, for example, of ZnO doped with Al, B, Ga, Sb etc., ITO (indium tin oxide), SnO₂, or a combination thereof. The transparent electrodes 38 may have a single-layer structure or a laminated structure such as a two-layer structure. The thickness of the transparent electrodes 38, which is not particularly limited, is preferably 0.3 μm to 1 μm.

The method of forming the transparent electrodes 38 is not particularly limited; they may be formed by coating techniques or vapor-phase film deposition techniques such as electron beam vapor deposition and sputtering.

The buffer layers 36 are provided to protect the photoelectric conversion layers 34 when forming the transparent electrodes 38 and to allow the light impinging on the transparent electrodes 38 to enter the photoelectric conversion layers 34.

The buffer layers 36 is made of, for example, CdS, ZnS, ZnO, ZnMgO, or ZnS (O, OH), or a combination thereof.

The buffer layers 36 preferably have a thickness of 0.03 μm to 0.1 μm. The buffer layers 36 are formed by, for example, chemical bath deposition (CBD) method.

The photoelectric conversion layer 34 has a photoelectric conversion function, such that it generates current by absorbing light that has reached it through the transparent electrode 38 and the buffer layer 36. In this embodiment, the photoelectric conversion layers 34 are not particularly limited in structure; they are made of, for example, at least one compound semiconductor of a chalcopyrite structure. The photoelectric conversion layers 34 may be made of at least one kind of compound semiconductor composed of a group Ib element, a group IIIb element, and a group VIb element.

For high optical absorbance and high photoelectric conversion efficiency, the photoelectric conversion layers 34 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te. Examples of the compound semiconductor include CuAlS₂, CuGaS₂, CuInS₂ CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂ and Ag(In₁₋ₓGaₓ) (S, Se)₂.

The photoelectric conversion layers 34 especially preferably contain CuInSe₂(CIS) and/or Cu(In, Ga)Se₂ (CIGS), which is obtained by solid-dissolving (solute) Ga in the former. CIS and GIGS are semiconductors each having a chalcopyrite crystal structure, and reportedly have high optical absorbance and high photoelectric conversion efficiency. Further, CIS and CIGS have less deterioration of the efficiency under exposure to light and exhibit excellent durability.

The photoelectric conversion layer 34 contains impurities for obtaining the desired semiconductor conductivity type. Impurities may be added to the photoelectric conversion layer 34 by diffusion from adjacent layers and/or direct doping into the photoelectric conversion layer 34. There may be a concentration distribution of constituent elements of group semiconductors and/or impurities in the photoelectric conversion layer 34, which may contain a plurality of layer regions formed of materials having different semiconductor properties such as n-type, p-type, and i-type.

For example, in a CIGS semiconductor, when provided with a distribution in the amount of Ga in the direction of thickness in the photoelectric conversion layer 34, the band gap width, carrier mobility, etc. can be controlled, and thus high photoelectric conversion efficiency is achieved.

The photoelectric conversion layers 34 may contain one or two or more kinds of semiconductors other than group I-III-VI semiconductors. Examples of semiconductors other than group I-III-VI semiconductors include a semiconductor formed of a group IVb element such as Si (group IV semiconductor), a semiconductor formed of a group IIIb element and a group Vb element such as GaAs (group III-V semiconductor), and a semiconductor formed of a group IIb element and a group VIb such as CdTe (group II-VI semiconductor). The photoelectric conversion layers 34 may contain any other component than a semiconductor and impurities used to obtain a desired conductivity type, provided that no detrimental effects are thereby produced on the properties.

The amount of a group semiconductor in the photoelectric conversion layers 34 is not particularly limited. The ratio of group semiconductor contained in the photoelectric conversion layers 34 is preferably 75 mass % or more and, more preferably, 95 mass % or more and, most preferably, 99 mass % or more.

Note that when the photoelectric conversion layers 34 in this embodiment are made of compound semiconductors formed of a group Ib element, a group IIIb element, and a group VIb element, the metal base 12 is preferably formed of carbon steel or ferrite stainless steel, and the back electrodes 32 are preferably made of molybdenum.

Exemplary known methods of forming the CIGS layer include 1) simultaneous multi-source co-evaporation method, 2) selenization method, 3) sputtering method, 4) hybrid sputtering method, and 5) mechanochemical processing method.

1) Known multi-source co-evaporation methods include: the three-stage method (J. R. Tuttle et al., Mat. Res. Soc. Symp. Proc., Vol. 426 (1966), p. 143, etc.), and the co-evaporation method of the EC group (L. Stolt et al.: Proc. 13th ECPVSEC (1995, Nice), 1451, etc.).

According to the former three-phase method, firstly, In, Ga and Se are simultaneously vapor-deposited under high vacuum at a substrate temperature of 300° C., which is then increased to 500° C. to 560° C. to simultaneously vapor-deposit Cu and Se, whereupon In, Ga and Se are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:
a) Method using ionized Ga (H. Miyazaki et al., Phys. Stat. Sol. (a), Vol. 203 (2006), p. 2603, etc.);
b) Method using cracked Se (a pre-printed collection of speeches given at the 68th Academic Lecture by the Japan Society of Applied Physics) (autumn, 2007, Hokkaido Institute of Technology), 7P-L-6, etc.);
c) Method using radicalized Se (a pre-printed collection of speeches given at the 54th Academic Lecture by the Japan Society of Applied Physics) (spring, 2007, Aoyama Gakuin Univ.), 29P-ZW-10, etc.); and
d) Method using a light excitation process (a pre-printed collection of speeches given at the 54th Academic Lecture by the Japan Society of Applied Physics) (spring, 2007, Aoyama Gakuin Univ.), 29P-ZW-14, etc.).

2) The selenization method is also called a two-stage method, whereby firstly a metal precursor formed of a laminated film such as a Cu layer/In layer, a (Cu—Ga) layer/In layer, or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells 35 (1994), 204-214, etc.); and a method in which selenium is sandwiched between thin metal films (e.g., as in Cu layer/In layer/Se layer . . . Cu layer/In layer/Se layer) to form a multi-layer precursor film (T. Nakada et al., Proc. of 10th European Photovoltaic Solar Energy Conference (1991), 887-890, etc.).

An exemplary method of forming a graded band gap GIGS film is a method which involves first depositing a Cu—Ga alloy film, depositing an In film thereon, and selenizing, while making a Ga concentration gradient in the film thickness direction using natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputter deposition methods include:
a technique using CuInSc₂ polycrystal as a target, one called two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658 etc.) and
a technique called three-source sputtering whereby a Cu target, an In target, and an Se or CuSe target are sputtered in Ar gas (T. Nakada at al., Jpn. J. Appl. Phys. 32 (1993), L1169-L1172, etc.).

4) Exemplary known methods for hybrid sputtering include the aforementioned sputtering method in which Cu and Tr metals are subjected to DC stuttering, while only Se is vapor-deposited (T. Nakada et al., Jpn. Appl. Phys. 34 (1995), 4715-4721, etc.).

5) An exemplary method for mechanochemical processing includes one in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming CIGS films include screen printing, close-spaced sublimation, MOCVD and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

The alkali supply layer 50 is to provide alkali metal, for example, during formation of the photoelectric conversion layer 34 so as to diffuse the alkali metal, such as Na, for example, into the photoelectric conversion layer 34 (CIGS layer) In this embodiment, the alkali supply layer 50 is preferably made of soda lime glass. When the alkali supply layer 50 is made of soda lime glass, RF sputtering can be used, for example.

The alkali supply layer 50 may have a single-layer structure, or may have a multiple-layer structure in which layers of different compositions are laminated.

Exemplary alkali metals include Li, Na, K, Rb, and Cs. Exemplary alkali-earth metals include Be, Mg, Ca, Sr, and Ba. For reasons such as ease of achieving a chemically safe and easy-to handle compound, ease of discharge from the alkali supply layer 50 by heat, and a high crystallinity improvement effect of the photoelectric conversion layers 34, the alkali metal is preferably at least one kind selected from Na, K, R and Cs, more preferably Na and/or K, and specially preferably Na.

Additionally, since a thick alkali supply layer 50 makes the layers more susceptible to delamination, the alkali supply layer 50 preferably has a thickness of 50 nm to 200 nm.

In this embodiment, since the content (density) of the alkali metal of the alkali supply layer 50 is sufficiently high, even when the film thickness of the alkali supply layer 50 is 50 nm to 200 nm, alkali metals sufficient to improve the conversion efficiency can be supplied to the photoelectric conversion layer 34.

Next, the manufacturing method of the thin-film solar cell 30 of the embodiment will be described.

First, the substrate 10 formed as described above is first prepared.

Next, a soda lime glass film, for example, is formed on the front surface 16a of one insulation layer 16 of the substrate 10 as the alkali supply layer 50 by RF sputtering using a film deposition apparatus.

Then, a molybdenum film serving as the back electrodes 32 is formed on the surface 50a of the alkali supply layer 50 by sputtering using, for example, a film deposition apparatus.

Then, for example, laser scribing is used to scribe the molybdenum film at the first predetermined position to form the separation grooves (P1) 33 extending in the width direction of the substrate 10. The back electrodes 32 separated from each other by the separation grooves (P1) 33 are thus formed.

Then, for example, a CIGS layer, which serves as a photoelectric conversion layer 34 (p-type semiconductor layer), is formed by any of the film deposition methods described above using a film deposition apparatus, so as to cover the back electrodes 32 and fill in the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Then, laser scribing is used to scribe the second position, which differs from the first position of the separation grooves (P1) 33, so as to form grooves (P2) 37 extending in the width direction of the substrate 10 and reach the back electrodes 32.

Then, a layer of ZnO doped with, for example, Al, B, Ga, Sb or the like, which serves as the transparent electrodes 38, is formed on the buffer layer 36 by sputtering or coating using a film deposition apparatus so as to fill the grooves (P2) 37.

Then, laser scribing is used to scribe a third position, which differs from the first position of the separation grooves (P1) 33 and the second position of the grooves (P2) 37, so as to form opening grooves (P3) 39 extending in the width direction of the substrate 10 and reach the back electrodes 32. Thus, a plurality of the power generating cells 54 are formed on the laminated body of the substrate 10 and the alkali supply layer 50 to form the power generating layer 56.

Then, the photoelectric conversion elements 40 formed on the rightmost and leftmost back electrodes 32 in the longitudinal direction L of the substrate 10 are removed by, for example, laser scribing or mechanical scribing, to expose the back electrodes 32. Then, the first conductive member 42 and the second conductive member 44 are connected by, for example, ultrasonic soldering onto the rightmost and leftmost back electrodes 32, respectively.

The thin-film solar cell 30 in which the plurality of photoelectric conversion elements 40 are connected in series can be thus manufactured as shown in FIG. 5.

If necessary, a bond/seal layer (not shown), a water vapor barrier layer (not shown), and a surface protection layer (not shown) are arranged on the front side of the suiting thin-film solar cell 30, and a bond/seal layer (not shown) and a back sheet (not shown) are formed on the back side of the thin-film solar cell 30, that is, on the back side of the substrate 10, and these layers are integrated by, vacuum lamination, for example. A thin-film solar cell module is thus obtained.

In the thin-film solar cell 30 in this embodiment, the porous anodized film of the insulation layer 16 is provided with the Martens hardness of 1000 N/mm² to 3500 N/mm² and the substrate 10 with the ratio of the average pore size to the average wall thickness of 0.2 to 0.5 so that even if it is placed outdoors and is subjected to severe temperature changes, external impact, or time-dependent change to cause damage to the Al base 14 and anodized film, the spread of cracks is suppressed and insulation (withstand voltage characteristics) is maintained. Thereby, long term reliability for insulation is maintained, and the thin-film solar cell 30 that offers excellent endurance and storage life is achieved. In addition, the thin-film solar cell module also has excellent durability and storage life.

Further, in the thin-film solar cell 30 in this embodiment, for example, even if the substrate 10 is exposed to a hot environment over 500° C. when the photoelectric conversion layer 34 is formed, the difference of the linear thermal expansion coefficients between the anodized film and the metallic substrate 15 lowers the tensile stress applied to the anodized film; thereby defects such as breaks and cracks are not generated. Therefore, the photoelectric conversion layer 34 can be formed at high temperatures. The compound semiconductor comprising the photoelectric conversion layer 34 can improve the photoelectric conversion characteristics when formed at higher temperatures, and thus, in this way as well, it is possible to manufacture the photoelectric conversion element 40 having the photoelectric conversion layers 34 with improved photoelectric conversion characteristics.

Furthermore, addition of the alkali supply layer 50 allows controlling the precision and reproducibility of the amount of alkali metal supplied to the photoelectric conversion layer 34 (CIGS layer). The conversion efficiency of the Photoelectric conversion elements 40 can be thus improved and the photoelectric conversion elements 40 can be thus manufactured at a high yield.

Also, in this embodiment, the substrate 10 is produced by the roll-to-roll process, is flexible, and is resistant to a bending strain. This makes it possible to manufacture the photoelectric conversion element 40 and the thin-film solar cell 30 as well using the roll-to-roll process, while transporting the substrate 10 in the longitudinal direction L. With the thin-film solar cell 30 thus manufactured using the inexpensive roll-to-roll process, the cost of manufacturing the thin-film solar cell 30 can be reduced. As a result, the cost of a thin-film solar cell module can be reduced.

In the thin-film solar cell 30 in this embodiment, the diffusion prevention layer may be provided between the alkali supply layer 50 and the insulation layer 16 in order to prevent the alkali metal contained in the alkali supply layer 50 from diffusing to the substrate 10 and to increase the amount of the alkali metal diffused to the photoelectric conversion layer 34. In this case, since the amount of the alkali metal diffused to the photoelectric conversion layer 34 can be increased, the photoelectric conversion element 40 with higher conversion efficiency can be obtained.

Further, the provision of the diffusion prevention layer makes it possible to achieve favorable conversion efficiency of the photoelectric conversion element even if the alkali supply layer is thin. In this embodiment, since the alkali supply layer 50 can be made thin, it is possible to shorten the fabrication time of the alkali supply layer 50 and improve the productivity of the photoelectric conversion element 40 and thus the thin-film solar cell 30. This also makes it possible to keep the alkali supply layer 50 from becoming the origin of delamination.

The diffusion prevention layer can be made of nitrides, for example, and is preferably an insulator.

Specifically, as a diffusion prevention layer of nitride TiN (9.4 ppm/K), ZrN (7.2 ppm/K), BN (6.4 ppm/K), and AlN (5.7 ppm/K) can be used. Of these, the diffusion prevention layer is preferably a material having a small difference in thermal expansion coefficient from that of the insulation layer 16 and aluminum anodized film of the substrate 10, and is thus more preferably made of ZrN, BN, or AlN. Of these, the insulators are BN and AlN, and these are more preferable as diffusion prevention layers.

The diffusion prevention layer may be made of oxide. In this case, TiO₂ (9.0 ppm/K), ZrO₂ (7.6 ppm/K), HfO₂ (6.5 ppm/K), and Al₂O₃ (8.4 ppm/K) can be used as oxide. The diffusion prevention layer is preferably an insulator even when it is made of oxide.

Presumably, while the oxide film prevents diffusion of Na to the substrate 10 due to Na within the film, the nitride film does not readily contain alkali metal such as Na within the film and thus inhibits diffusion to the inside of the nitride film, thereby promoting Na diffusion to the CIGS layer more than the alkali supply layer. Therefore, as a diffusion prevention layer, the diffusion prevention layer of nitride is more effective than the diffusion prevention layer of oxide in diffusing the alkali metal into the photoelectric conversion layer 34 (CIGS layer). Therefore, the diffusion prevention layer of nitride is more preferable.

The diffusion prevention layer is preferably thick since increased thickness enhances its function of preventing diffusion into the substrate 10 and its function of increasing the amount of alkali metal diffused into the photoelectric conversion layers 34. Nevertheless, since a greater thickness causes the diffusion prevention layer to become the origin of delamination, the diffusion prevention layer preferably has a thickness of 10 nm to 200 nm, and more preferably 10 nm to 100 nm.

In this embodiment, the diffusion prevention layer is made of an insulator, making it possible to further improve the insulation properties (withstand voltage characteristics) of the substrate 10. Further, as described above, the substrate 10 exhibits excellent heat resistance. The thin-film solar cell 30 can thus exhibit even better durability and storage life. For this reason, the thin-film solar cell module also has better durability and storage life.

In this embodiment, the substrate 10 is used for the substrate of the thin-film solar cell, but the present invention is not limited thereto. The substrate can be used for a thermoelectric module that generates electricity using the difference of temperature using, for example, a thermoelectric element. When it is used for a thermoelectric module, a thermoelectric element can be integrated and connected in series.

Further, in addition to the thermoelectric module, for example, various semiconductor elements can be formed on the substrate 10 to provide a semiconductor device. In this semiconductor device as well, the roll-to-roll process can be used for formation of semiconductor elements. Therefore, the roll-to-roll process for formation of semiconductor elements is preferably used for higher productivity.

The present invention is basically as described above. The metal substrate with an insulation layer and a method for manufacturing the same, a semiconductor device and a method for manufacturing the same, and a solar cell and a method for manufacturing the same according to the present invention have been described above in detail, but the present invention is by no means limited to the above embodiments, and various improvements or design modifications may be made without departing from the spirit and scope of the present invention.

### EXAMPLE 1

Example 1 of the metal substrate with an insulation layer of the present invention will be specifically described below.

In this Example 1, a single material of the high purity aluminum material with the purity of 99.99% was used and an anodized film was formed on the high purity aluminum material under the anodization conditions A to L shown in the following Table 1. The pore size/wall thickness, the Martens hardness, the Vickers hardness, the Young's modulus, and crack length/indentation length of each anodized film were measured. The results are shown in Table 2.

The anodized film was observed for the pore size/wall thickness with a scanning electron microscope and 20 cells among the cells formed on the anodized film were measured for the wall thickness and the pore size to determine the average value of wall thickness and the average value of the pore size. The pore size/wall thickness is the ratio of the average value of the pore size and the average value of wall thickness.

The Martens hardness, the Vickers hardness, and the Young's modulus of each anodized film were simultaneously measured using a PICODENTOR™ HM500H made by Fischer Instruments.

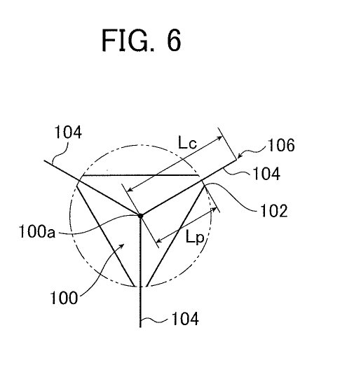

As for the crack length/indentation length, a Berkovich indenter is pushed in to this anodized film about 10 μm with the anodized film formed on the substrate to form the indentation 100 and the crack 104 as shown in FIG. 6. The indentation 100 and the crack 104 were observed with an optical microscope to measure the length Lp of the indentation 100 (hereinafter referred to as the indentation length Lp) and the length Lc of the crack 104 (hereinafter referred to as the crack length Lc). Cracks are not necessarily formed when the Berkovich indenter is pushed in about 10 μm.

The indentation length Lp was the length from the center 100a of the indentation 100 to the end 102 of the indentation 100. The crack length Lc was the length from the center 100a of the indentation 100 to the end 106 of the crack 104.

In this Example 1, the crack length/indentation length was used as an indicator for now easy cracks were formed. Smaller value of crack length/indentation length suggests the cracking resistance is higher.

TABLE 1

| Anodization | | Temperature | Voltage | Film |
|---|---|---|---|---|
| conditions | Acid | (° C.) | (V) | thickness (μm) |
| A | 1M sulfuric | 35 | 15 | 10 |
| | acid | | | |
| B | 1M malonic | 16 | 80 | 10 |
| | acid | | | |
| C | 1M malonic | 80 | 80 | 20 |
| | acid | | | |
| D | 1M tartaric | 80 | 160 | 10 |
| | acid | | | |
| E | 0.5M oxalic | 5 | 60 | 10 |
| | acid | | | |
| F | 0.5M oxalic | 16 | 40 | 10 |
| | acid | | | |
| G | 0.5M oxalic | 16 | 40 | 20 |
| | acid | | | |
| H | 0.5M oxalic | 16 | 50 | 10 |
| | acid | | | |
| I | 0.5M oxalic | 35 | 40 | 10 |
| | acid | | | |
| J | 0.5M oxalic | 55 | 40 | 10 |
| | acid | | | |
| K | 0.5M oxalic | 75 | 40 | 5 |
| | acid | | | |
| L | 0.5M oxalic | 75 | 30 | 7 |
| | acid | | | |

TABLE 2

| | Evaluation result | | | | |
|---|---|---|---|---|---|
| | | | | | Crack |
| Ano- | pore | Martens | Vickers | Young's | length/ |
| dization | size/wall | hardness | hardness | modulus | indentation |
| conditions | thickness | (N/mm²) | Hv | (GPa) | length |
| A | 0.45 | 2.0 × 10³ | 245 | 58 | 1.5 |
| B | 0.30 | 3.2 × 10³ | 410 | 105 | 2.2 |
| C | 0.37 | 2.4 × 10³ | 298 | 82 | 1.6 |
| D | 0.42 | 3.5 × 10³ | 441 | 106 | No crack |
| | | | | | was formed |
| E | 0.33 | 4.6 × 10³ | 624 | 125 | 2.5 |
| F | 0.35 | 3.8 × 10³ | 505 | 106 | 1.9 |
| G | 0.35 | 4.0 × 10³ | 551 | 105 | 2.0 |
| H | 0.39 | 3.9 × 10³ | 512 | 108 | 1.9 |
| I | 0.51 | 2.9 × 10³ | 409 | 80 | 1.7 |
| J | 0.63 | 2.1 × 10³ | 262 | 63 | 1.4 |
| K | 0.61 | 1.7 × 10 | 2 | Cannot be | 1.2 |
| | | | | measured | |
| L | 0.96 | 2.1 × 10 | 2 | Cannot be | 1.1 |
| | | | | measured | |

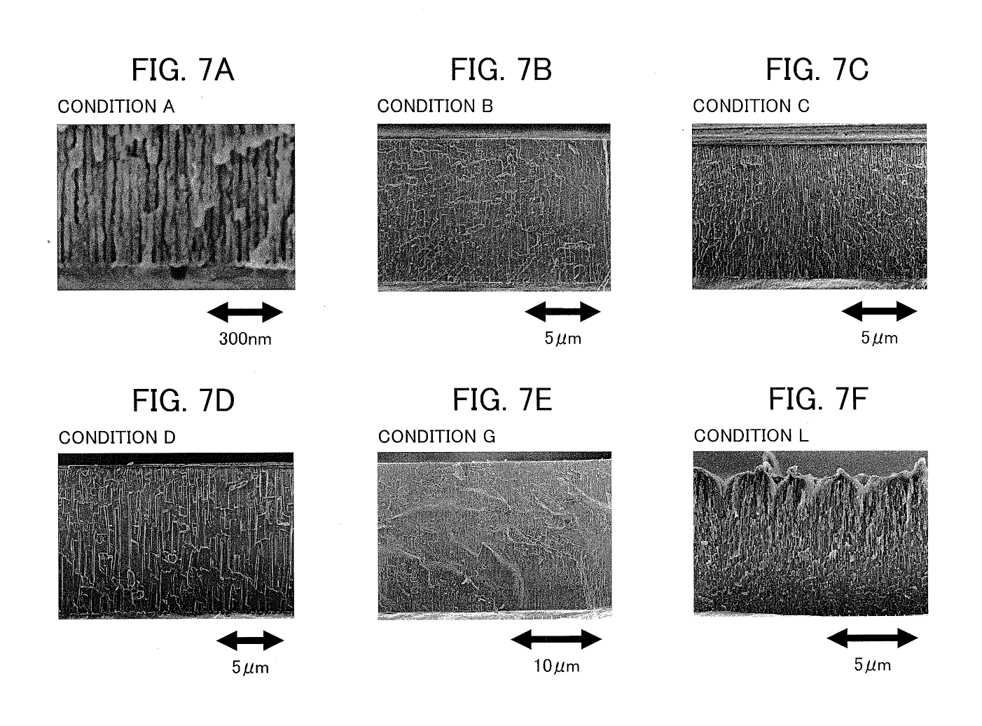

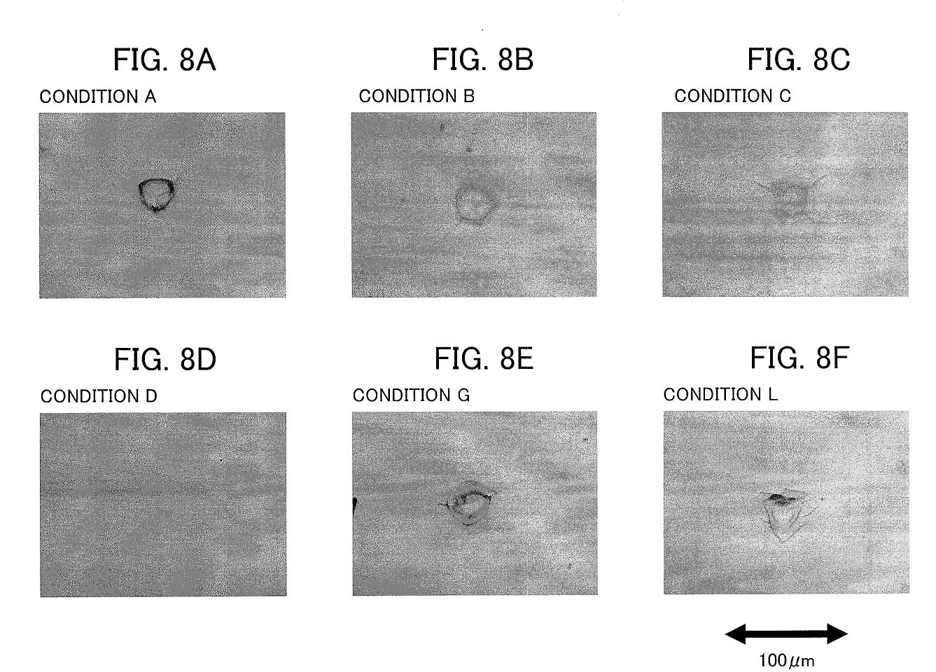

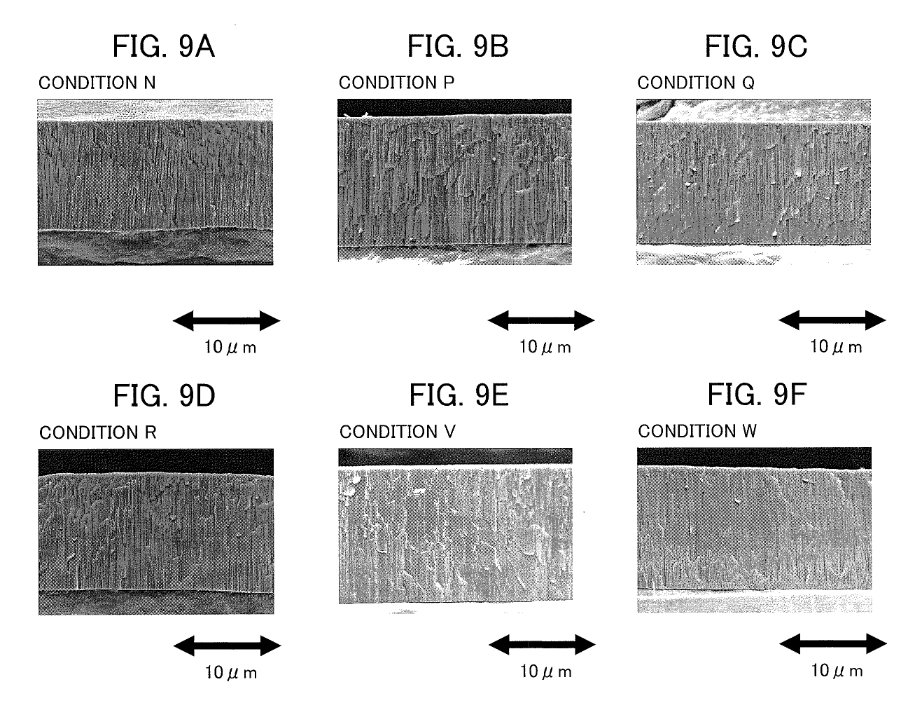

FIG. 7 shows the anodized film formed under the anodization conditions A to D, G, and L among the anodization conditions shown in the Table 1. FIG. 8 shows the indentation formed in order to measure the crack length/indentation length of the anodized film formed under the anodization conditions of A to D, G, and L.

The Martens hardness under the anodization conditions A to D are 1000 N/mm² to 3500 N/mm², and the porous anodized film with the ratio of the average pore size to the average wall thickness of 0.2 to 0.5 was obtained. The observation of the indentation shown in FIG. 8 suggests that they have high cracking resistance. Especially, under the anodization conditions C and D, a porous anodized film with the magnitude of the compressive strain of 0.00% to 0.1% was obtained at room temperature. The observation of the indentation suggests that they have especially high cracking resistance. The observation of the indentation suggests that cracking resistance is high under the anodization condition L. Under the anodization conditions K and L, the thickness of the anodized film was close to the critical film thickness, and the Young's modulus was not able to be measured.

Next, an anodized film was formed on the aluminum substrate of the high purity aluminum material with the thickness of 300 μm and with the purity of 99.99% under each of the above-mentioned anodization conditions A to L, metal substrates with insulation layers according to the working examples 1 to 4 and the comparison examples 1 to 8 were prepared, and the magnitude of the strain and the internal stress of the anodized film respectively forming the insulation layer 16 were measured. The results are shown in Table 3.

Annealing treatment was not performed on the metal substrates with insulation layers of the working examples 10 to 12 and the comparison examples 10 to 15.

A bending strain test, a thermal strain test, and an electric insulation evaluation test were performed on the metal substrate with an insulation layer of each of the working examples 1 to 4 and the comparison examples 1 to 8 to evaluate the bending strain resistance, thermal strain resistance, and electric insulation. The results are shown in Table 3.

For the metal substrate with an insulation layer of each of the working examples 1 to 4 and the comparison examples 1 to 8, the magnitude of strain was calculated, as described above, by measuring the length of the anodized film of the metal substrate with an insulation layer, then by measuring the length of the anodized film after dissolving and removing the aluminum substrate, and based the length of the anodized film before and after removing the aluminum substrate.

Further, for the metal substrate with an insulation layer of each of the working examples 1 to 4 and the comparison examples 1 to 8, the Young's modulus was measured using a PICODENTOR™ HM500H made by Fischer Instruments, and the internal stress was determined using the magnitude of the strain and the Young's modulus.

In the bending strain test, the metal substrate with an insulation layer of each of the working examples 1 to 4 and the comparison examples 1 to 8 were respectively cut into test specimens of 3 cm in width and 10 cm in length. Each test specimen was bent along the jig with the radius of curvature shown in the following Table 3 to observe the front surface of each test specimen with the optical microscope.

In the bending strain test, bending strain resistance was assessed by the degree of cracking. If no cracking was seen in the test specimen, the example was marked with an O. If cracking occurred but stopped part way through the 3 cm width, it was marked with a triangle. If cracking occurred along the entire surface of the test specimen, it was marked with an X.

In the thermal strain test, for the metal substrate with an insulation layer of each of the working examples 1 to 4 and the comparison examples 1 to 8, the existence of cracks on the anodized film was checked after rapidly raising the temperature at 500 K/min. from room temperature to each test temperature, holding for 15 minutes, and then lowering the temperature to room temperature.

For crack generation, a visual examination was performed on the intact metal substrate with an insulation layer, and it was also performed using an optical microscope on the insulation layer after the metal substrate was removed by dissolving and the insulation was taken oil. The results are shown in Table 3.

If there was no cracking seen by either visual or optical microscope observation, the example was marked with an O. If there was no cracking seen by visual observation but there was cracking seen by optical microscope observation, the example was marked with a triangle. If cracking was seen by both visual and optical microscope observation, it was marked with an X.

In the electric insulation evaluation test, the metal substrate with an insulation layer of each of the working example 1 to 4 and the comparison examples 1 to 8 was respectively cut into test specimens of 4 cm×4 cm to form a top gold electrode with the diameter of 2 cm.

After forming the top gold electrode at each test specimen, voltage of 10 V was applied, and successively increased by 10 V one by one, and the value of the applied voltage when the insulation was destroyed was measured to use as a breakdown voltage. Four samples were measured respectively, and the average value of the three samples excluding the sample that had insulation destroyed at the lowest voltage was used as a breakdown voltage. When insulation was not destroyed at 1000 V, “1000 V or more” was marked in the column of breakdown voltage.

TABLE 3

| | | | | | | | | | | Thermal strain | | | | |
|---|---|---|---|---|---|---|---|---|---|---|---|---|---|---|
| | | | | | | Bending strain | | | | test: | | | | |
| | | | | | | test: Radius of | | | | Heating temperature | | | | |
| | Anodization | Strain at room | | Internal stress | | curvature (mm) | | | | (° C.) | | | | Breakdown |
| | conditions | temperature | | (MPa) | | 30 | 50 | 80 | 100 | 120 | 150 | 180 | 210 | Voltage (V) |
| Working | A | 0.010% | Tensile | 6 | Tensile | X | X | ◯ | ◯ | ◯ | ◯ | Δ | X | 1000 V or |
| example 1 | | | | | | | | | | | | | | more |
| Working | B | 0.005% | Tensile | 5 | Tensile | X | X | ◯ | ◯ | ◯ | ◯ | Δ | X | 1000 V or |
| example 2 | | | | | | | | | | | | | | more |
| Working | C | 0.086% | Compressive | 71 | Compressive | X | ◯ | ◯ | ◯ | ◯ | ◯ | ◯ | X | 1000 V or |
| example 3 | | | | | | | | | | | | | | more |
| Working | D | 0.097% | Compressive | 103 | Compressive | X | ◯ | ◯ | ◯ | ◯ | ◯ | ◯ | X | 1000 V or |
| example 4 | | | | | | | | | | | | | | more |
| Comparison | E | 0.021% | Tensile | 26 | Tensile | X | X | X | ◯ | X | X | X | X | 1000 V or |
| example 1 | | | | | | | | | | | | | | more |
| Comparison | F | 0.008% | Tensile | 8 | Tensile | X | X | ◯ | ◯ | ◯ | Δ | X | X | 1000 V or |
| example 2 | | | | | | | | | | | | | | more |
| Comparison | G | 0.042% | Tensile | 44 | Tensile | X | X | X | ◯ | ◯ | Δ | X | X | 1000 V or |
| example 3 | | | | | | | | | | | | | | more |
| Comparison | H | 0.024% | Tensile | 26 | Tensile | X | X | X | ◯ | ◯ | Δ | X | X | 1000 V or |
| example 4 | | | | | | | | | | | | | | more |
| Comparison | I | 0.046% | Tensile | 37 | Tensile | X | X | X | ◯ | ◯ | ◯ | X | X | 1000 V or |
| example 5 | | | | | | | | | | | | | | more |
| Comparison | J | 0.024% | Compressive | 15 | Compressive | X | X | ◯ | ◯ | ◯ | ◯ | Δ | X | 970 |
| example 6 | | | | | | | | | | | | | | |
| Comparison | K | 0.031% | Compressive | — | Compressive | X | X | ◯ | ◯ | ◯ | ◯ | Δ | X | 340 |
| example 7 | | | | | | | | | | | | | | |
| Comparison | L | 0.029% | Compressive | — | Compressive | X | X | ◯ | ◯ | ◯ | ◯ | Δ | X | 520 |
| example 8 | | | | | | | | | | | | | | |

The bending strain resistance, thermal strain resistance, and electric insulation of the working examples 1 to 4 and the comparison examples 1 to 8 were respectively compared. In this case, the working examples 1 and 2 showed the same level of the bending strain resistance and thermal strain resistance as the working examples 6 to 8 and had better electric insulation than those of the comparison examples 6 to 8.

The working examples 3 and 4 showed no crack until the test specimens were bent to a smaller radius of curvature than those in the comparison examples 1 to 8, and the working examples 3 and 4 had high bending strain resistance. Further, the working examples 3 and 4 showed no crack until at temperatures higher than those in comparison examples 1 to 8, and the working examples 3 and 4 had high thermal strain resistance. In addition, they showed good electric insulation.

The comparison examples 7 and 8 produced under the anodization conditions K and L were on the condition near the critical film thickness of the anodized film. The cross section of the anodized film obtained under the anodization conditions L is illustrated in FIG. 7F as an example. The observation of the indentation (shown in FIG. 8F) suggests that they have high cracking resistance. As shown in Table 3, the comparison examples 7 and 8 have high bending strain resistance and thermal strain resistance, but have low electric insulation. The comparison examples 7 and 8 are not suitable as semiconductor devices or solar cell substrates that require long term reliability of insulation because they lack electric insulation, surface properties, and hardness (refer to Table 2), etc.

### EXAMPLE 2

In this Example 2, using two-layer cladding substrate of a aluminum plate (30 μm in thickness) with the purity of 99.99% and a SUS430 stainless steel plate (100 μm in thickness), an anodized film was formed on the aluminum plate under the anodization conditions A, C, D, F, G, I, J, K, and L from the anodization conditions shown in the above-mentioned Table 1 to obtain the metal substrates with insulation layers of the working examples 10 to 12 and the comparison examples 10 to 15. Annealing treatment was not performed on the metal substrates with insulation layers of the working examples 10 to 12 and the comparison examples 10 to 15.

The metal substrate with an insulation layer of each of the working examples 10 to 12 and the comparison examples 10 to 15 was measured for the magnitude of the strain and internal stresses of the anodized film forming the insulation layers, respectively. The results are shown in Table 4.

A bending strain test, a thermal strain test, and an electric insulation evaluation test were performed on the metal substrate with an insulation layer of each of the working examples 10 to 12 and the comparison examples 10 to 15 to evaluate the bending strain resistance, thermal strain resistance, and electric insulation. The results are shown in Table 4.

Since the magnitude of the strain, the Young's modulus, and internal stress of the anodized film were measured in the same manner as the above-mentioned example 1, a detailed description thereof will be omitted.

Further, the bending strain test, the thermal strain test, and the electric insulation evaluation test were also performed in the same manner as the above-mentioned example 1 to evaluate the bending strain resistance, thermal strain resistance, and electric insulation in the same manner as the above-mentioned example 1.

TABLE 4

| | | | | | | Bending | | | | | | | | | |
|---|---|---|---|---|---|---|---|---|---|---|---|---|---|---|---|
| | | | | | | strain | | | | | | | | | |
| | | | | | | test: Radius | | | | | | | | | Break- |
| | Anodi- | | | | | of curvature | | | Thermal strain test: | | | | | | down |
| | zation | Strain at room | | Internal stress | | (mm) | | | Heating temperature (° C.) | | | | | | Voltage |
| | conditions | temperature | | (MPa) | | 20 | 30 | 50 | 450 | 500 | 525 | 550 | 575 | 590 | (V) |
| Working | A | 0.009% | Tensile | 5 | Tensile | X | ◯ | ◯ | ◯ | ◯ | ◯ | X | X | X | 1000 V or |
| example 10 | | | | | | | | | | | | | | | more |
| Working | C | 0.029% | Compressive | 24 | Compressive | X | ◯ | ◯ | ◯ | ◯ | ◯ | ◯ | Δ | X | 1000 V or |
| example 11 | | | | | | | | | | | | | | | more |
| Working | D | 0.039% | Compressive | 41 | Compressive | X | ◯ | ◯ | ◯ | Δ | Δ | Δ | X | X | 1000 V or |
| example 12 | | | | | | | | | | | | | | | more |
| Comparison | F | 0.031% | Tensile | 33 | Tensile | X | X | ◯ | ◯ | Δ | X | X | X | X | 1000 V or |
| example 10 | | | | | | | | | | | | | | | more |
| Comparison | G | 0.042% | Tensile | 44 | Tensile | X | X | ◯ | ◯ | Δ | X | X | X | X | 1000 V or |
| example 11 | | | | | | | | | | | | | | | more |
| Comparison | I | 0.026% | Tensile | 21 | Tensile | X | X | Δ | ◯ | Δ | X | X | X | X | 1000 V or |
| example 12 | | | | | | | | | | | | | | | more |
| Comparison | J | 0.009% | Compressive | 6 | Compressive | X | X | ◯ | ◯ | ◯ | X | X | X | X | 1000 V or |
| example 13 | | | | | | | | | | | | | | | more |
| Comparison | K | 0.030% | Compressive | — | Compressive | X | ◯ | ◯ | ◯ | ◯ | ◯ | Δ | X | X | 390 |
| example 14 | | | | | | | | | | | | | | | |
| Comparison | L | 0.021% | Compressive | — | Compressive | X | ◯ | ◯ | ◯ | ◯ | ◯ | Δ | X | X | 550 |
| example 15 | | | | | | | | | | | | | | | |

The bending strain resistance, thermal strain resistance, and electric insulation of the working examples 10 to 12 and the comparison examples 10 to 15 were respectively compared. In this case, the working examples 10 to 12 showed the same level of bending strain resistance as in the comparison examples 14 and 15, but no crack was formed when the text pieces were bent to the radius of curvature smaller than those in the comparison examples 10 to 13.

Further, the working example 11 showed no crack until at a temperature higher than those in comparison examples 10 to 15, and the working example 11 had high thermal strain resistance.

The comparison examples 14 and 15 showed the same level of thermal strain resistance as in the working examples 11 and 12. However, the comparison examples 14 and 15 showed lower electric insulation than those in the working examples 10 to 12.

The comparison examples 14 and 15 produced under the anodization conditions K and L were on the condition near the critical film thickness of the anodized film. The cross section of the anodized film obtained under the anodization condition L is illustrated in FIG. 7F as an example. The observation of the indentation (shown in FIG. 8F) suggests that they have high cracking resistance. As shown in Table 4, the comparison examples 14 and 15 have high bending strain resistance and thermal strain resistance, but have low electric insulation. The comparison examples 14 and 15 are not suitable as semiconductor devices or solar cell substrates that require long term reliability of insulation because they lack electric insulation, surface properties, and hardness (refer to Table 2), etc.

### EXAMPLE 3

In this Example 3, using a two-layer cladding substrate of an aluminum plate (30 μm in thickness) with the purity of 99.99% and a SUS430 stainless steel plate (100 μm in thickness), an anodized film was formed on the aluminum plate under the anodization conditions A and M to W from the anodization conditions shown in the above-mentioned Table 1 and the following Table 5 to obtain a metal substrate with an insulation layer. Then, annealing treatment was performed under the annealing conditions shown in the following Table 6. Thus, the metal substrate with an insulation layer of each of the working examples 20 to 49 was produced by performing annealing treatment on the anodized film.

The metal substrate with an insulation layer of each of the working examples 20 to 49 was measured for the magnitude of the strain and internal stresses of the anodized film forming the insulation layers, respectively. The results are shown in Table 6.

The porous type anodized film with the magnitude of the compressive strain of 0.005% to 0.3% was obtained at room temperature by annealing.

A bending strain test, a thermal strain test, and an electric insulation evaluation test were performed on the metal substrate with an insulation layer of each of the working examples 20 to 49 to evaluate the bending strain resistance, thermal strain resistance, and electric insulation. The results are shown in Table 7.

Since the magnitude of the strain, the Young's modulus, and the internal stress of the anodized film were measured in the same manner as the above-mentioned example 1, a detailed description thereof will be omitted.

Further, the bending strain test, the thermal strain test, and the electric insulation evaluation test were also performed in the same manner as the above-mentioned example 1 to evaluate the bending strain resistance, thermal strain resistance, and electric insulation in the same manner as the above-mentioned example 1.

TABLE 5

| Anodization | | Temperature | Voltage | Film |
|---|---|---|---|---|
| conditions | Acid | (° C.) | (V) | thickness (μm) |
| M | 1M malonic | 80 | 80 | 10 |
| | acid | | | |
| N | 1M malonic | 50 | 120 | 10 |
| | acid | | | |
| O | 0.5M oxalic | 40 | 60 | 10 |
| | acid | | | |
| P | 0.5M oxalic | 50 | 60 | 10 |
| | acid | | | |
| Q | 0.5M oxalic | 30 | 60 | 10 |
| | acid | | | |
| R | 0.5M oxalic | 30 | 80 | 10 |
| | acid | | | |
| S | 0.5M oxalic | 40 | 50 | 10 |
| | acid | | | |
| T | 0.5M oxalic | 40 | 70 | 10 |
| | acid | | | |
| U | 0.5M oxalic | 50 | 40 | 10 |
| | acid | | | |
| V | 0.5M oxalic | 60 | 40 | 10 |
| | acid | | | |
| W | 0.5M oxalic | 60 | 60 | 10 |
| | acid | | | |

TABLE 6

| | | | | Diameter | | | | | | | | |
|---|---|---|---|---|---|---|---|---|---|---|---|---|
| | | Annealing | | of | | | Crack | | | | | |
| | Anodi- | conditions | | pores/ | Martens | Vickers | length/ | | | Young's | | |
| | zation | Temp | Time | wall | hardness | hardness | indentation | Strain at room | | modulus | Internal Stress | |
| | conditions | (° C.) | (minute) | thickness | (N/mm²) | Hv | length | temperature | | (GPa) | (MPa) | |
| Working | M | — | — | 0.37 | 2.4 × 10³ | 294 | 1.6 | 0.030% | Compressive | 82 | 25 | Compressive |
| example | | | | | | | | | | | | |
| 20 | | | | | | | | | | | | |
| Working | M | 250 | 15 | 0.37 | 2.5 × 10³ | 305 | Not | 0.054% | Compressive | 79 | 43 | Compressive |
| example | | | | | | | measured | | | | | |
| 21 | | | | | | | | | | | | |
| Working | M | 350 | 15 | 0.37 | 2.6 × 10³ | 320 | Not | 0.102% | Compressive | 72 | 73 | Compressive |
| example | | | | | | | measured | | | | | |
| 22 | | | | | | | | | | | | |
| Working | M | 450 | 15 | 0.37 | 2.6 × 10³ | 334 | No crack | 0.172% | Compressive | 69 | 119 | Compressive |
| example | | | | | | | was | | | | | |
| 23 | | | | | | | formed | | | | | |
| Working | M | 350 | 5 | 0.37 | 2.6 × 10³ | 326 | Not | 0.047% | Compressive | 78 | 37 | Compressive |
| example | | | | | | | measured | | | | | |
| 24 | | | | | | | | | | | | |
| Working | M | 350 | 100 | 0.37 | 2.6 × 10³ | 333 | Not | 0.120% | Compressive | 75 | 90 | Compressive |
| example | | | | | | | measured | | | | | |
| 25 | | | | | | | | | | | | |
| Working | M | 350 | 1000 | 0.37 | 2.6 × 10³ | 333 | Not | 0.123% | Compressive | 76 | 93 | Compressive |
| example | | | | | | | measured | | | | | |
| 26 | | | | | | | | | | | | |
| Working | N | 450 | 15 | 0.37 | 2.8 × 10³ | 408 | Not | 0.180% | Compressive | 80 | 144 | Compressive |
| example | | | | | | | measured | | | | | |
| 27 | | | | | | | | | | | | |
| Working | A | 250 | 15 | 0.45 | 2.0 × 10³ | 245 | Not | 0.042% | Compressive | 72 | 30 | Compressive |
| example | | | | | | | measured | | | | | |
| 28 | | | | | | | | | | | | |
| Working | A | 350 | 15 | 0.45 | 2.0 × 10³ | 254 | Not | 0.110% | Compressive | 67 | 74 | Compressive |
| example | | | | | | | measured | | | | | |
| 29 | | | | | | | | | | | | |
| Working | A | 450 | 15 | 0.45 | 2.1 × 10³ | 270 | Not | 0.088% | Compressive | 65 | 57 | Compressive |
| example | | | | | | | measured | | | | | |
| 30 | | | | | | | | | | | | |
| Working | A | 350 | 5 | 0.45 | 2.0 × 10³ | 281 | Not | 0.097% | Compressive | 71 | 69 | Compressive |
| example | | | | | | | measured | | | | | |
| 31 | | | | | | | | | | | | |
| Working | A | 350 | 100 | 0.45 | 2.0 × 10³ | 278 | Not | 0.102% | Compressive | 79 | 81 | Compressive |
| example | | | | | | | measured | | | | | |
| 32 | | | | | | | | | | | | |
| Working | A | 350 | 200 | 0.45 | 2.0 × 10³ | 279 | Not | 0.119% | Compressive | 68 | 81 | Compressive |
| example | | | | | | | measured | | | | | |
| 33 | | | | | | | | | | | | |
| Working | A | 350 | 1000 | 0.45 | 2.0 × 10³ | 280 | Not | 0.124% | Compressive | 71 | 88 | Compressive |
| example | | | | | | | measured | | | | | |
| 34 | | | | | | | | | | | | |
| Working | O | — | — | 0.41 | 2.5 × 10³ | 321 | Not | 0.021% | Tensile | 109 | 23 | Tensile |
| example | | | | | | | measured | | | | | |
| 35 | | | | | | | | | | | | |
| Working | O | 250 | 15 | 0.41 | 2.6 × 10³ | 336 | Not | 0.038% | Compressive | 121 | 46 | Compressive |
| example | | | | | | | measured | | | | | |
| 36 | | | | | | | | | | | | |
| Working | O | 350 | 15 | 0.41 | 2.7 × 10³ | 350 | Not | 0.096% | Compressive | 118 | 114 | Compressive |
| example | | | | | | | measured | | | | | |
| 37 | | | | | | | | | | | | |
| Working | O | 450 | 15 | 0.41 | 2.7 × 10³ | 368 | Not | 0.168% | Compressive | 123 | 207 | Compressive |
| example | | | | | | | measured | | | | | |
| 38 | | | | | | | | | | | | |
| Working | P | — | — | 0.36 | 2.2 × 10³ | 295 | Not | 0.003% | Tensile | 102 | 3 | Tensile |
| example | | | | | | | measured | | | | | |
| 39 | | | | | | | | | | | | |
| Working | P | 250 | 15 | 0.36 | 2.3 × 10³ | 307 | Not | 0.049% | Compressive | 124 | 61 | Compressive |
| example | | | | | | | measured | | | | | |
| 40 | | | | | | | | | | | | |
| Working | P | 350 | 15 | 0.36 | 2.3 × 10³ | 325 | Not | 0.132% | Compressive | 109 | 144 | Compressive |
| example | | | | | | | measured | | | | | |
| 41 | | | | | | | | | | | | |
| Working | P | 450 | 15 | 0.36 | 2.4 × 10³ | 335 | Not | 0.183% | Compressive | 115 | 211 | Compressive |
| example | | | | | | | measured | | | | | |
| 42 | | | | | | | | | | | | |
| Working | Q | 450 | 15 | 0.42 | 3.2 × 10³ | 419 | Not | 0.174% | Compressive | 91 | 158 | Compressive |
| example | | | | | | | measured | | | | | |
| 43 | | | | | | | | | | | | |
| Working | R | 450 | 15 | 0.33 | 3.3 × 10³ | 446 | Not | 0.180% | Compressive | 90 | 162 | Compressive |
| example | | | | | | | measured | | | | | |
| 44 | | | | | | | | | | | | |
| Working | S | 450 | 15 | 0.43 | 2.4 × 10³ | 332 | Not | 0.193% | Compressive | 71 | 137 | Compressive |
| example | | | | | | | measured | | | | | |
| 45 | | | | | | | | | | | | |
| Working | T | 450 | 15 | 0.36 | 2.4 × 10³ | 327 | Not | 0.167% | Compressive | 62 | 104 | Compressive |
| example | | | | | | | measured | | | | | |
| 46 | | | | | | | | | | | | |
| Working | U | 450 | 15 | 0.43 | 2.2 × 10³ | 308 | Not | 0.157% | Compressive | 59 | 93 | Compressive |
| example | | | | | | | measured | | | | | |
| 47 | | | | | | | | | | | | |
| Working | V | 450 | 15 | 0.21 | 1.9 × 10³ | 231 | Not | 0.195% | Compressive | 56 | 109 | Compressive |
| example | | | | | | | measured | | | | | |
| 48 | | | | | | | | | | | | |
| Working | W | 450 | 15 | 0.36 | 1.8 × 10³ | 224 | Not | 0.196% | Compressive | 48 | 94 | Compressive |
| example | | | | | | | measured | | | | | |
| 49 | | | | | | | | | | | | |

TABLE 7

| | Bending | | | | | | | | | |
|---|---|---|---|---|---|---|---|---|---|---|
| | strain test: | | | | | | | | | |
| | Radius | | | | | | | | | |
| | of curvature | | | Thermal strain test: | | | | | | |
| | (mm) | | | Heating temperature (° C.) | | | | | | Breakdown |
| | 20 | 30 | 50 | 450 | 500 | 525 | 550 | 575 | 590 | Voltage (V) |
| Working | X | ◯ | ◯ | ◯ | ◯ | ◯ | ◯ | X | X | 1000 V or |
| example 20 | | | | | | | | | | more |
| Working | Δ | ◯ | ◯ | ◯ | ◯ | ◯ | ◯ | X | X | 1000 V or |
| example 21 | | | | | | | | | | more |
| Working | ◯ | ◯ | ◯ | ◯ | ◯ | ◯ | ◯ | ◯ | X | 1000 V or |
| example 22 | | | | | | | | | | more |
| Working | ◯ | ◯ | ◯ | ◯ | ◯ | ◯ | ◯ | ◯ | X | 1000 V or |
| example 23 | | | | | | | | | | more |
| Working | ◯ | ◯ | ◯ | ◯ | ◯ | ◯ | ◯ | ◯ | X | 1000 V or |
| example 24 | | | | | | | | | | more |
| Working | ◯ | ◯ | ◯ | ◯ | ◯ | ◯ | ◯ | ◯ | X | 1000 V or |
| example 25 | | | | | | | | | | more |
| Working | ◯ | ◯ | ◯ | ◯ | ◯ | ◯ | ◯ | ◯ | X | 1000 V or |
| example 26 | | | | | | | | | | more |
| Working | ◯ | ◯ | ◯ | ◯ | ◯ | ◯ | ◯ | Δ | X | 1000 V or |
| example 27 | | | | | | | | | | more |
| Working | X | ◯ | ◯ | ◯ | ◯ | ◯ | X | X | X | 1000 V or |
| example 28 | | | | | | | | | | more |
| Working | Δ | ◯ | ◯ | ◯ | ◯ | ◯ | Δ | Δ | X | 1000 V or |
| example 29 | | | | | | | | | | more |
| Working | ◯ | ◯ | ◯ | ◯ | ◯ | ◯ | ◯ | Δ | X | 1000 V or |
| example 30 | | | | | | | | | | more |
| Working | Δ | ◯ | ◯ | ◯ | ◯ | ◯ | ◯ | X | X | 1000 V or |
| example 31 | | | | | | | | | | more |
| Working | Δ | ◯ | ◯ | ◯ | ◯ | ◯ | Δ | Δ | X | 1000 V or |
| example 32 | | | | | | | | | | more |
| Working | ◯ | ◯ | ◯ | ◯ | ◯ | ◯ | ◯ | Δ | X | 1000 V or |
| example 33 | | | | | | | | | | more |
| Working | ◯ | ◯ | ◯ | ◯ | ◯ | ◯ | ◯ | Δ | X | 1000 V or |
| example 34 | | | | | | | | | | more |
| Working | X | Δ | ◯ | ◯ | ◯ | Δ | X | X | X | 1000 V or |
| example 35 | | | | | | | | | | more |
| Working | X | ◯ | ◯ | ◯ | ◯ | ◯ | Δ | X | X | 1000 V or |
| example 36 | | | | | | | | | | more |
| Working | X | ◯ | ◯ | ◯ | ◯ | ◯ | Δ | X | X | 1000 V or |
| example 37 | | | | | | | | | | more |
| Working | X | ◯ | ◯ | ◯ | ◯ | ◯ | Δ | X | X | 1000 V or |
| example 38 | | | | | | | | | | more |
| Working | X | Δ | ◯ | ◯ | ◯ | Δ | X | X | X | 1000 V or |
| example 39 | | | | | | | | | | more |
| Working | X | ◯ | ◯ | ◯ | ◯ | ◯ | X | X | X | 1000 V or |
| example 40 | | | | | | | | | | more |
| Working | X | ◯ | ◯ | ◯ | ◯ | ◯ | Δ | X | X | 1000 V or |
| example 41 | | | | | | | | | | more |
| Working | X | ◯ | ◯ | ◯ | ◯ | ◯ | Δ | X | X | 1000 V or |
| example 42 | | | | | | | | | | more |
| Working | X | ◯ | ◯ | ◯ | ◯ | ◯ | Δ | X | X | 1000 V or |
| example 43 | | | | | | | | | | more |
| Working | X | ◯ | ◯ | ◯ | ◯ | ◯ | Δ | X | X | 1000 V or |
| example 44 | | | | | | | | | | more |
| Working | Δ | ◯ | ◯ | ◯ | ◯ | ◯ | ◯ | X | X | 1000 V or |
| example 45 | | | | | | | | | | more |
| Working | X | ◯ | ◯ | ◯ | ◯ | ◯ | Δ | X | X | 1000 V or |
| example 46 | | | | | | | | | | more |
| Working | X | ◯ | ◯ | ◯ | ◯ | ◯ | Δ | X | X | 1000 V or |
| example 47 | | | | | | | | | | more |
| Working | ◯ | ◯ | ◯ | ◯ | ◯ | ◯ | ◯ | X | X | 1000 V or |
| example 48 | | | | | | | | | | more |
| Working | Δ | ◯ | ◯ | ◯ | ◯ | ◯ | ◯ | X | X | 1000 V or |
| example 49 | | | | | | | | | | more |

The bending strain resistance, thermal strain resistance, and electric insulation of the working examples 20 to 49 were compared with those of the comparison examples 10 to 15 (refer to Table 4) of the above-mentioned example 2.

The working examples 20 to 49 showed the same level of bending strain resistance as those in the comparison examples 14 and 15, but no crack was formed when the text pieces were bent to the radius of curvature smaller than those in the comparison examples 10 to 13.

In addition, the working examples 20 to 49 showed the same level of thermal strain resistance as those in the comparison examples 14 and 15, but no crack was formed until at a temperature higher than those in the comparison examples 10 to 13.

The comparison examples 14 and 15 showed the bending strain resistance and thermal strain resistance higher than those in the working examples 20 to 49 in some cases, but the electric insulation was lower than those in the working examples 20 to 49. Thus, the comparison examples 14 and 15 are not suitable as semiconductor devices or solar cell substrates that require long term reliability of insulation because they lack electric insulation, surface properties, and hardness (refer to Table 2), etc.

In the working examples 21 to 26, annealing treatment was performed to the anodized film of the working example 20 at various temperatures. In the working examples 28 to 34, annealing treatment was performed to the anodized film of the working example 10 (refer to Table 4) of the above-mentioned example 2 at various temperatures. In the working examples 36 to 38, annealing treatment was performed to the anodized film of the working example 35 at various temperatures. In the working examples 40 to 42, annealing treatment was performed to the anodized film of the working example 39 at various temperatures. These comparisons indicate the value of the pore size/wall thickness does not change and the hardness hardly changes as well before and after annealing treatment.

On the other hand, although the internal stress of the anodized film was tensile strain in the working examples 20, 35, and 39 with no annealing treatment performed, annealing treatment changed it to a compressive strain. The magnitude of the compressive stress is larger when the temperature of annealing treatment is higher. A porous type anodized film with the magnitude of the compressive strain of 0.005% to 0.3% was obtained at room temperature by annealing.

For the bending strain resistance and thermal strain resistance, no crack was formed when the test specimens were bent to a smaller radius of curvature and the bending strain resistance was higher in the working examples 21 to 26, the working examples 28 to 34, the working examples 36 to 38, and the working examples 40 to 42 with annealing treatment performed than those in the working example 10 (refer to Table 4), the working example 20, the working example 35, and the working example 39 without annealing treatment performed. Further, no crack was formed at a higher temperature, and the thermal strain resistance was higher. The working examples 21 to 26, the working examples 28 to 34, the working examples 36 to 38, and the working examples 40 to 42 all indicated that the compressive stress caused by annealing treatment made it difficult for cracks to form.

For the electric insulation, the working examples 20 to 49 all showed the breakdown voltage of 1000 V or higher.

Thus, in the metal substrate with an insulation layer, the Martens hardness of the anodized film is 1000 N/mm² to 3500 N/mm² and the ratio of the average pore size to the average wall thickness is 0.2 to 0.5. The metal substrate with an insulation layer has an electric insulation, surface properties, hardness as showed in Table 2, and so it can be suitably used as semiconductor devices and solar cell substrates that require long term reliability of insulation. Further, the metal substrate with an insulation layer of which the anodized film has a compressive strain at room temperature and the magnitude of the strain is 0.005% to 0.3% can be used more suitably as semiconductor devices and solar cell substrates.

What is claimed is:

1. A metal substrate with an insulation layer, comprising:
a metallic substrate having at least an aluminum base; and
an insulation layer formed on said aluminum base of said metallic substrate,
wherein said insulation layer is a anodized film of aluminum, and
wherein said anodized film has a porous structure having plural pores and a Martens hardness of 1000 N/mm² to 3500 N/mm², and a ratio of an average pore size of said plural pores to an average wall thickness of said plural pores ranges from 0.2 to 0.5.

2. The substrate with an insulation layer according to claim 1, wherein said anodized film has a compressive strain at room temperature, and a magnitude of said strain ranges from 0.005% to 0.3%.

3. The substrate with an insulation layer according to claim 1, wherein said anodized film is formed by electrolysis in an aqueous solution at a temperature of 50° C. or more, said aqueous solution containing acid having an acid dissociation constant (pKa) of 2.5 to 3.5 at a temperature of 25° C.

4. The substrate with an insulation layer according to claim 2, wherein said anodized film is obtained by anodizing said aluminum base to form a first insulation layer, and subjecting the thus formed first insulation layer to a heat treatment at a heating temperature of 100° C. to 600° C.

5. The substrate with an insulation layer according to claim 4, wherein said first insulation layer has a tensile strain.

6. The substrate with an insulation layer according to claim 1, wherein a thickness of said anodized film ranges from 1 μm to 20 μm.

7. The substrate with an insulation layer according to claim 1, wherein
said metallic substrate is made of said aluminum base, and
said anodized film is formed on at least one surface of said aluminum base.

8. The substrate with an insulation layer according to claim 1, wherein said metallic substrate further includes a metal base, and said aluminum base is formed on at least one surface of said metal base.

9. The substrate with an insulation layer according to claim 8, wherein
said metal base is made of metal different from aluminum, and
said anodized film is formed on a surface of said aluminum base.

10. The substrate with an insulation layer according to claim 8, wherein
said metal base is made of metal having a larger Young's modulus than aluminum, and
said anodized film is formed on a surface of said aluminum base.

11. The substrate with an insulation layer according to claim 8, wherein a linear thermal expansion coefficient of said metal base is larger than a linear thermal expansion coefficient of said anodized film, and is smaller than a linear thermal expansion coefficient of aluminum.

12. The substrate with an insulation layer according to claim 8, wherein a Young's modulus of said metal base is larger than a Young's modulus of said anodized film, and is larger than a Young's modulus of aluminum.

13. The substrate with an insulation layer according to claim 8, wherein said metal base and said aluminum base are intergraded by pressure welding.

14. A method for manufacturing a metal substrate with an insulation layer, comprising:
preparing a metallic substrate having at least an aluminum base; and
forming an anodized film as an insulation layer on said aluminum base of said metallic substrate,
wherein said anodized film is formed by electrolysis in an aqueous solution at a temperature of 50° C. or more, said aqueous solution containing acid having an acid dissociation constant (pKa) of 2.5 to 3.5 at a temperature of 25° C.

15. The manufacturing method according to claim 14,
wherein said metallic substrate further includes a metal base, and said aluminum base is formed on at least one surface of said metal base, and
wherein said metal base and said aluminum base are intergraded by pressure welding.

16. The manufacturing method according to claim 14, wherein said anodized film is formed by using a roll-to-roll process.

17. A semiconductor device, comprising:
the metal substrate with an insulation layer according to claim 1, and
a semiconductor element formed on said metal substrate with the insulation layer.

18. A method for manufacturing a semiconductor device, comprising:
forming the metal substrate with an insulation layer by using the manufacturing method according to claim 14, and
forming a semiconductor element on said metal substrate with the insulation layer by using a roll-to-roll process.

19. A solar cell, comprising:
the metal substrate with an insulation layer according to claim 1, and
a photoelectric conversion layer formed on said metal substrate with the insulation layer.

20. The solar cell according to claim 19, wherein said photoelectric conversion layer is a compound-based photoelectric conversion layer.

21. A method for manufacturing a solar cell, comprising:
forming the metal substrate with an insulation layer by using the manufacturing method according to claim 14, and
forming at least a back electrode and a photoelectric conversion layer on said metal substrate with the insulation layer by using a roll-to-roll process.
